(19) United States
(12) Patent Application Publication
(10) Pub. No.: US 2010/0227046 A1
(43) Pub. Date: Sep. 9, 2010

(54) FILM DEPOSITION APPARATUS, FILM DEPOSITION METHOD, AND COMPUTER READABLE STORAGE MEDIUM

(75) Inventors: HITOSHI KATO, Oshu-Shi (JP); Manabu Honma, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/713,250

(22) Filed: Feb. 26, 2010

(30) Foreign Application Priority Data
Mar. 4, 2009 (JP) 2009-051257

(51) Int. Cl. C23C 16/52; C23C 16/00

(52) U.S. Cl. 427/10; 118/712; 118/665; 427/9

(57) ABSTRACT

A disclosed film deposition apparatus includes a transparent window in a ceiling plate of a vacuum chamber. A film thickness of a film deposited on a substrate is measured by emitting light to the substrate through the transparent window by a film thickness measurement system that includes optical units arranged on or above the transparent window, optical fiber cables connected to the corresponding optical units, a measurement unit to which the optical fiber cables are connected, and a control unit electrically connected to the measurement unit in order to control the measurement unit.

### CROSS-REFERENCE TO RELATED APPLICATION

This application claims the benefit of priority of Japanese Patent Application No. 2009-051257, filed on Mar. 4, 2009 with the Japanese Patent Office, the entire contents of which are hereby incorporated by reference.

### BACKGROUND OF THE INVENTION

1. Field of the Invention

The present invention relates to a film deposition apparatus and a film deposition method that enable film thickness monitoring during film deposition, and a computer readable storage medium storing a program for causing the film deposition apparatus to perform the film deposition method.

2. Description of the Related Art

In fabrication of semiconductor integrated circuits, various film deposition processes are carried out in order to deposit various films on a substrate. Along with further miniaturization of circuit patterns and thinning of films for higher integration, further improvement in uniformity and controllability of a film thickness across a substrate has been required. As a film deposition method that can address such demands, an atomic layer deposition (ALD) method (also referred to as a molecular layer deposition (MLD) method) has been attracting attention (for example, Patent Document 1).

Some film deposition apparatuses preferable for the ALD method use a susceptor on which 2 through 6 wafers are placed flat. In such film deposition apparatuses, there are provided a rotatable susceptor, and a gas nozzle for a first compound source gas, a gas nozzle for a purge gas, a gas nozzle for a second compound source gas, and a gas nozzle for a purge gas that are arranged in this order above and extend in a radial direction of the susceptor. When the gases are supplied from the corresponding nozzles and the susceptor is rotated, adsorption of the first compound source gas, purging the first compound source gas, adsorption of the second compound source gas, and purging the second compound source gas are carried out in this order with respect to the wafers placed on the susceptor. When the susceptor is rotated one revolution in such a manner, one layer of molecules of the first compound source gas and one layer of molecules of the second compound source gas are adsorbed on the wafers, so that one layer of reaction product is deposited on the wafers through chemical reaction of the first and the second compound source gases.

Therefore, the required number of rotations of the susceptor can be obtained by dividing a target film thickness of a material to be deposited by a thickness of one layer of the material, in principle, and the target film thickness is obtained with the number of rotations.

Patent Document 1: U.S. Pat. No. 6,646,235 (FIGS. 2 and 3).

Patent Document 2: Japanese Patent Application Laid-Open Publication No. 2003-224108.

However, it has been found by the inventors of the present invention that the film thickness cannot be determined only by the number of the rotations of the susceptor for the following various reasons. For example, a thickness of one molecular layer of the material to be deposited may be changed depending on film deposition conditions such as film deposition temperature. In addition, when the material is poly-crystalline or amorphous, a thickness (distance between adjacent atoms) of one layer of the material may be unknown, which is different from a single crystal material. Moreover, when a compound material is deposited, one layer of the material is changed depending on its crystalline compositions.

Furthermore, two layers of the molecules of the compound source gas may be adsorbed on the wafers due to a vapor pressure and intermolecular force depending on source gases to be used. Additionally, two layers of the molecules may be deposited on the wafers depending on a gas flow pattern of the source gases in a vacuum chamber, a rotational speed of the susceptor, a gas flow rate of the source gas, temperature variation in the susceptor, and the like.

Under such circumstances, the target film thickness cannot be necessarily realized by the number of rotations of the susceptor obtained by dividing the target film thickness by the thickness per one layer. Therefore, a test run for determining the number of rotations under a predetermined film deposition conditions is generally carried out in order to obtain the required number of rotations of the susceptor. Such a test run has to be carried out for various films to be deposited and for types of devices to be fabricated, which may cause problems of increased production costs and a decreased number of production runs.

While a method for detecting an end point even in a production run has been known in an etching apparatus for use in semiconductor device fabrication (for example, Patent Document 2), no sufficient consideration has been taken in the ALD method that is inherently excellent in film thickness controllability to the best knowledge of the inventor of the present invention. However, because further improvement in controllability and uniformity of film thickness is required in the future, film thickness monitoring during film deposition is desired.

### SUMMARY OF THE INVENTION

The present invention has been made in view of the above, and provides a film deposition apparatus and a film deposition method that enable film thickness monitoring during film deposition, and a computer readable storage medium storing a program for causing the film deposition apparatus to perform the film deposition method.

A first aspect of the present invention provides a film deposition apparatus for depositing a film on a substrate by carrying out a cycle of alternately supplying to the substrate at least two kinds of reaction gases that react with each other to produce a layer of a reaction product in a chamber. This film deposition apparatus includes a susceptor rotatably provided in the chamber and having in one surface thereof a substrate receiving area in which the substrate is placed; a window portion hermetically provided to the chamber so that the window portion opposes the susceptor in the chamber; a film thickness measurement portion that optically measures a thickness of a film deposited on the substrate placed in the substrate receiving area, through the window portion; a first reaction gas supplying portion configured to supply a first reaction gas to the one surface; a second reaction gas supplying portion configured to supply a second reaction gas to the one surface, the second reaction gas supplying portion being separated from the first reaction gas supplying portion along a rotation direction of the susceptor; a separation area located along the rotation direction between a first process area in which the first reaction gas is supplied and a second process area in which the second reaction gas is supplied; a center area that is located substantially in a center portion of the chamber, configured to separate the first process area and the second process area, and has an ejection hole that ejects a first separation gas along the one surface; and an evacuation opening provided in the chamber in order to evacuate the chamber. The separation area includes a separation gas supplying portion that supplies a second separation gas, and a ceiling surface that creates in relation to the one surface of the susceptor a thin space in which the second separation gas may flow from the separation area to the process area side in relation to the rotation direction.

A second aspect of the present invention provides a film deposition method for depositing a film on a substrate by carrying out a cycle of alternately supplying to the substrate at least two kinds of reaction gases that react with each other to produce a layer of a reaction product in a chamber. The film deposition method includes steps of placing the substrate in a substrate receiving area defined in one surface of a susceptor rotatably provided in the chamber; rotating the susceptor on which the substrate is placed; supplying a first reaction gas to the one surface of the susceptor from a first reaction gas supplying portion; supplying a second reaction gas to the one surface of the susceptor from a second reaction gas supplying portion separated from the first reaction gas supplying portion along a rotation direction of the susceptor; supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor; supplying a second separation gas from an ejection hole formed in a center area located in a center portion of the chamber; evacuating the chamber; and measuring a film thickness of a film deposited on the substrate placed on the susceptor rotated in the step of rotating the susceptor.

A third aspect of the present invention provides a computer readable storage medium storing a computer program for causing a film deposition apparatus according to the first aspect to carry out a film deposition method according to the second aspect.

### BRIEF DESCRIPTION OF THE DRAWINGS

FIG. 1 is a schematic view illustrating a film deposition apparatus according to an embodiment of the present invention;

FIG. 2 is a perspective view of an inner configuration of the film deposition apparatus of FIG. 1;

FIG. 3 is a top view of the inner configuration of the film deposition apparatus of FIG. 1;

FIG. 4 is a cross-sectional view of the inner configuration of the film deposition apparatus of FIG. 1;

FIG. 5 is a schematic view of a film thickness measurement system provided in the film deposition apparatus of FIG. 1;

FIG. 6 is a partial cross-sectional view of the film deposition apparatus of FIG. 1;

FIG. 7 is a broken perspective view of the film deposition apparatus of FIG. 1;

FIG. 8 is a partial cross-sectional view illustrating flows of purge gases in the film deposition apparatus of FIG. 1;

FIG. 9 is a perspective view illustrating a transfer arm that accesses a vacuum chamber of the film deposition apparatus of FIG. 1;

FIG. 10 is a plan view of a flow pattern of gases flowing in the vacuum chamber of the film deposition apparatus of FIG. 1;

FIG. 11 is an explanatory view for explaining a shape of a convex portion in the film deposition apparatus of FIG. 1;

FIG. 12 illustrates a modification example of a gas nozzle in the film deposition apparatus of FIG. 1;

FIG. 13 illustrates a modification example of the convex portion in the film deposition apparatus of FIG. 1;

FIG. 14 illustrates a modification example of the convex portion and the gas nozzle in the film deposition apparatus of FIG. 1;

FIG. 15 illustrates another modification example of the convex portion in the film deposition apparatus of FIG. 1;

FIG. 16 illustrates a modification example of an arrangement of the gas nozzles in the film deposition apparatus of FIG. 1;

FIG. 17 illustrates another modification example of the convex portion in the film deposition apparatus of FIG. 1;

FIG. 18 illustrates an example where the convex portion is provided for a reaction gas nozzle in the film deposition apparatus of FIG. 1;

FIG. 19 illustrates another modification example of the convex portion in the film deposition apparatus of FIG. 1;

FIG. 20 is a schematic view of a film deposition apparatus according to another embodiment of the present invention;

FIG. 21 is a schematic view illustrating a substrate processing apparatus including the film deposition apparatuses of FIG. 1 or FIG. 20;

FIG. 22 is a schematic view illustrating another substrate processing apparatus including the film deposition apparatuses of FIG. 1 or FIG. 20; and

FIG. 23 is a cross-sectional view taken along line II-II in FIG. 22.

### DETAILED DESCRIPTION OF THE PREFERRED EMBODIMENT

According to an embodiment of the present invention, there are provided a film deposition apparatus and a film deposition method that enable film thickness monitoring during film deposition, and a computer readable storage medium storing a program for causing the film deposition apparatus to perform the film deposition method.

Referring to the accompanying drawings, a film deposition apparatus according to an embodiment of the present invention will be explained in the following.

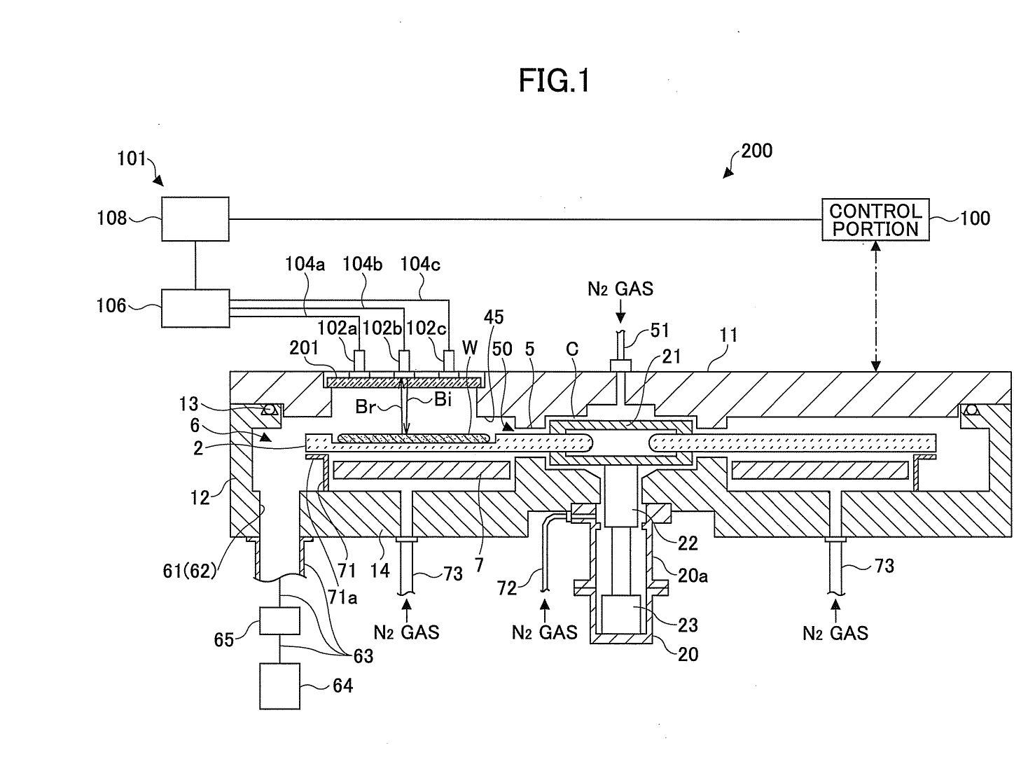

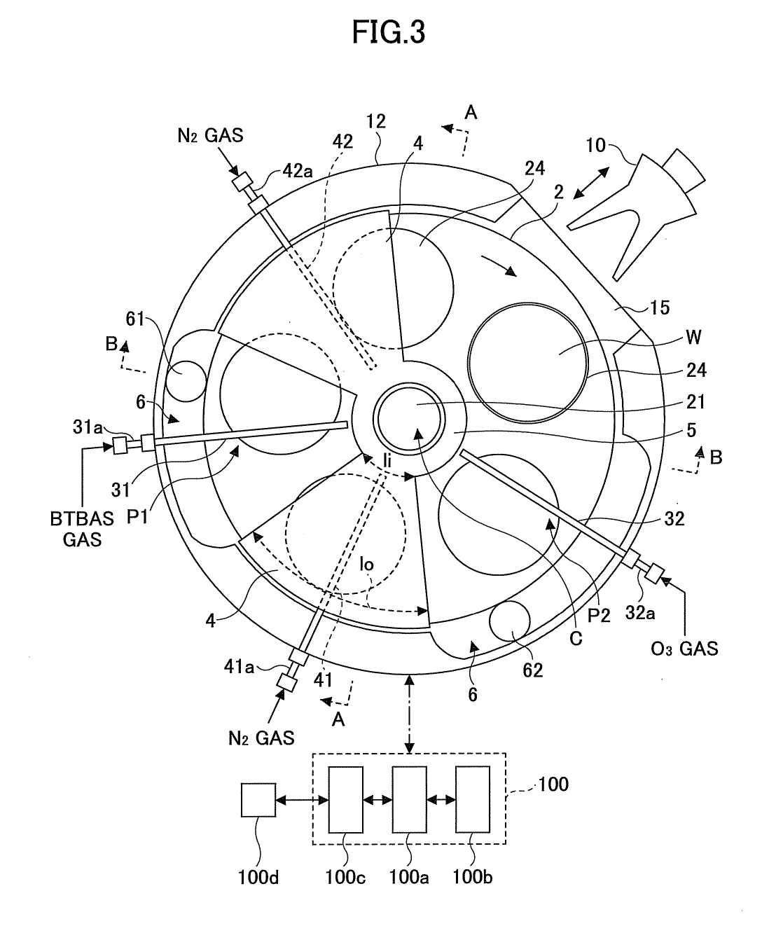

As shown in FIGS. 1 (a cross-sectional view taken along line B-B in FIG. 3), 2 and 3, a film deposition apparatus 200 according to an embodiment of the present invention is provided with a planar vacuum chamber 1 having a cylinder top view shape, and a susceptor 2 that is arranged inside the vacuum chamber 1 and has a rotation center at a center of the vacuum chamber 1. The vacuum chamber 1 is configured so that a ceiling plate 11 can be separated from a chamber body 12. The ceiling plate 11 is attached on the chamber body 12 via a sealing member 13 such as an O ring, so that the vacuum chamber 1 is hermetically sealed. Additionally, the ceiling plate 11 can be raised by a driving mechanism (not shown) when the ceiling plate 11 has to be removed from the chamber body 12.

The ceiling plate 11 is provided with a stepped opening, and a transparent window 201 is attached to the ceiling plate 11 by utilizing the step via a sealing member such as an O ring. With this, the transparent window 201 is hermetically attached to the vacuum chamber 1. The transparent window 201 is made of, for example, quartz glass, and used when a thickness of a film deposited on a wafer W is measured by a film thickness measurement system 101. In addition, the transparent window 201 may have a width substantially equal to a diameter of the wafer W placed on the susceptor 2, and the width extends in a radial direction of the susceptor 2, which enables thickness measurement at various points on the wafer W in the radial direction. The film thickness measurement system 101 relies on ellipsometry, in this embodiment.

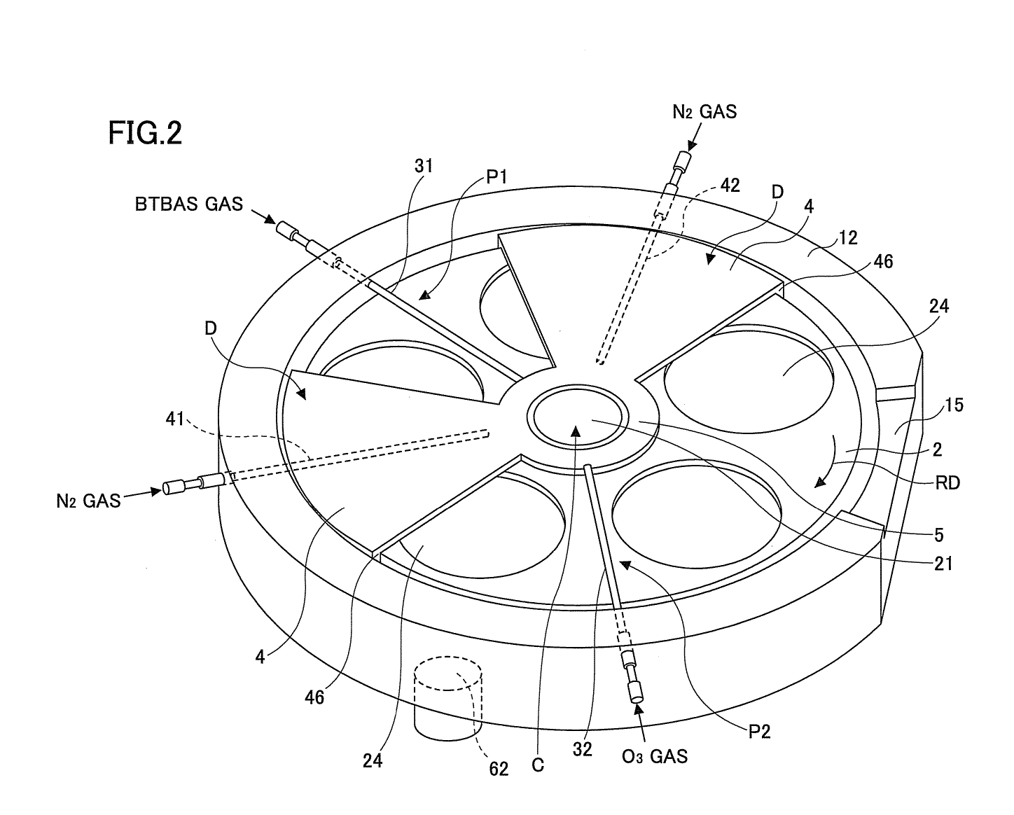

The susceptor 2 is made of a carbon plate having a thickness of about 20 mm and has a disk shape having a diameter of about 960 mm, in this embodiment. An upper surface, a bottom surface, and a side surface of the susceptor 2 may be coated with silicon carbide (SiC). The susceptor 2 may be made of other materials such as quartz in other embodiments. Referring to FIG. 1, the susceptor 2 has a circular opening portion substantially at the center, and is supported from above and below by a core member 21 around the circular opening. The core portion 21 is fixed on a top end of a rotational shaft 22 that extends in a vertical direction. The rotational shaft 22 penetrates a bottom portion 14 of the chamber body 12, and is attached at the bottom to a driving portion 23 that rotates the rotational shaft 22. With such a configuration, the susceptor 2 can rotate around its center, for example, in a rotation direction RD shown in FIG. 2. The rotational shaft 22 and the driving portion 23 are housed in a cylindrical case body 20 having an open top. The case body 20 is attached on a bottom surface of the bottom portion 14 of the vacuum chamber 1 via a flange portion 20a. With this, an inner atmosphere and outer atmosphere of the case body 20 are isolated.

As shown in FIGS. 2 and 3, plural (five in the illustrated example) wafer receiving portions 24 having a circular concave shape, each of which receives a wafer W, are formed in an upper surface of the susceptor 2, although only one wafer W is illustrated in FIG. 3. The wafer receiving portions 24 are arranged at equal angular intervals of about 72°.

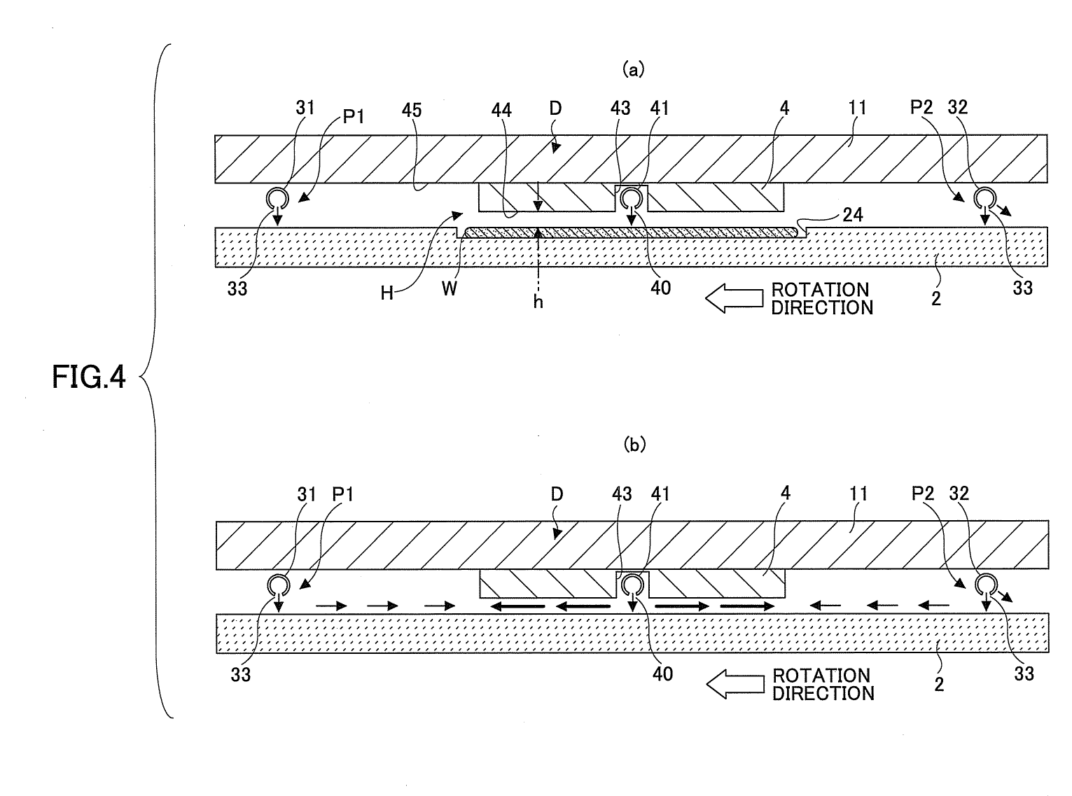

Referring to a subsection (a) of FIG. 4, the wafer receiving portion 24 and the wafer W placed in the wafer receiving portion 24 are illustrated. As shown in this drawing, the wafer receiving portion 24 has a diameter slightly larger, for example, by 4 mm than the diameter of the wafer W and a depth equal to a thickness of the wafer W. Therefore, when the wafer W is placed in the wafer receiving portion 24, a surface of the wafer W is at the same elevation of a surface of an area of the susceptor 2, the area excluding the wafer receiving portions 24. If there is a relatively large step between the area and the wafer W, gas flow turbulence is caused by the step, which may affect thickness uniformity across the wafer W. In order to avoid such degraded uniformity, the two surfaces are at the same elevation. While “the same elevation” may mean here that a height difference is less than or equal to about 5 mm, the difference has to be as close to zero as possible to the extent allowed by machining accuracy.

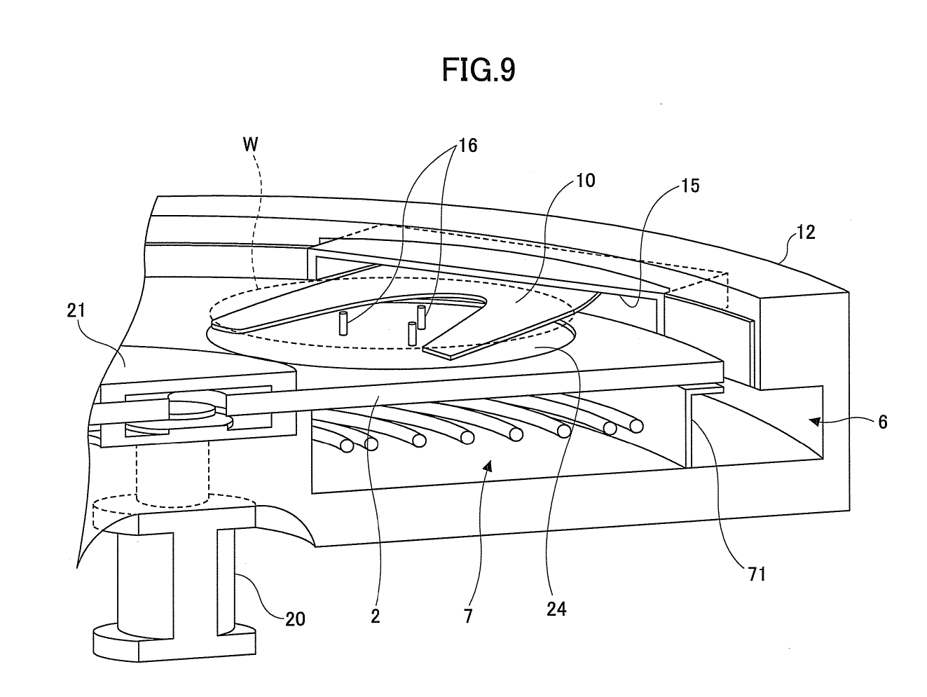

In addition, three through holes (not shown) are made at a bottom of the wafer receiving portion 24, and three lift pins (see FIG. 9) are moved up and down through the corresponding through holes. The lift pins support the wafer W from the bottom surface of the wafer W and moves the wafer W upward and downward.

As shown in FIGS. 2, 3, and 9, a transfer opening 15 is made on a side wall of the chamber body 12. The wafer W is transferred into and out from the vacuum chamber 1 through the transfer opening 15 by a transfer arm 10. The transfer opening 15 is provided with a gate valve (not shown), which opens and closes the transfer opening 15. When one of the wafer receiving portions 24 is aligned with the transfer opening 15 and the gate valve is opened, the wafer W is transferred into the vacuum chamber 1 by the transfer arm 10 and placed on the wafer receiving portion 24. In order to bring the wafer W down from the transfer arm 10 to the wafer receiving portion 24, the lift pins 16 (FIG. 9) are provided. The lift pins 16 are moved up and down through the through holes made in the wafer receiving portion 24 by an elevation mechanism (not shown). In such a manner, the wafer W is placed on the wafer receiving portion 24.

Referring again to FIG. 1, the film thickness measurement system 101 is provided above the transparent window 201. The film thickness measurement system 101 includes three optical units 102a through 102c arranged on (or above) the upper surface of the transparent window 201, optical fiber cables 104a through 104c connected to the corresponding optical units 102a through 102c, a measurement unit 106 to which the optical fiber cables 104a through 104c are optically connected, and a control unit 108 electrically connected to the measurement unit 106 in order to control the measurement unit 106. The control unit 108 may be a computer, connected to a control portion 100 that controls the film deposition apparatus 200 as a whole, and sends/receives signals to/from the control portion 100. With this, the film deposition apparatus 101 can cooperate with the film deposition apparatus 200.

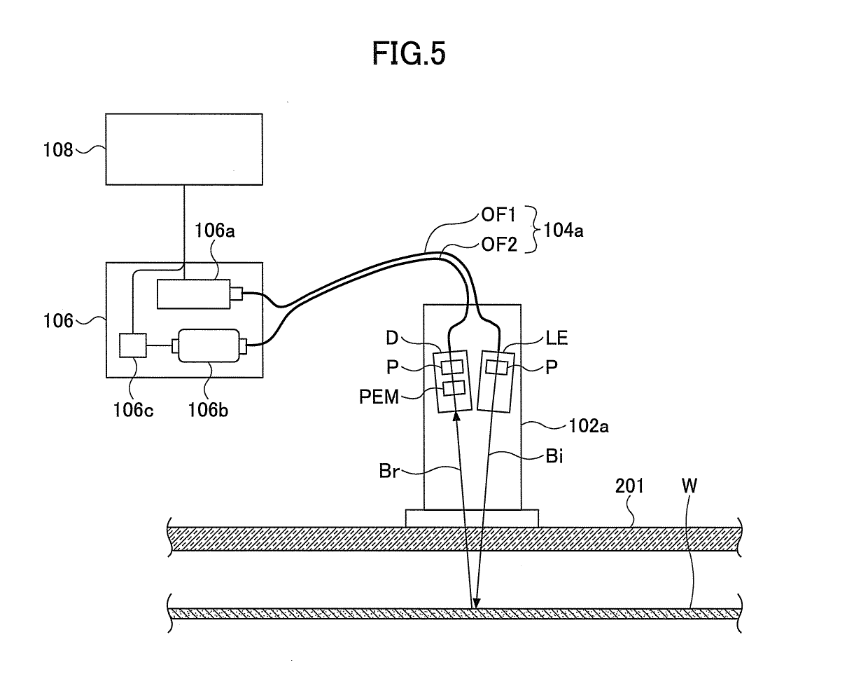

FIG. 5 is a schematic view illustrating the optical unit 102a and the measurement unit 106. As shown, the optical unit 102a has a light emitting portion LE and a light detecting portion D. The measurement unit 106 has a light source 106a including a xenon lamp, a spectroscope 106b, and a light detector 106c that detects light from the spectroscope 106b. In addition, the optical fiber cable 104a has two optical fibers OF1, OF2.

Incidentally, while omitted in FIG. 5, the optical units 102b, 102c have the same configuration as the optical unit 102a. In addition, the measurement unit 106 has additional spectroscopes 106b and light detectors 106c corresponding to the optical units 102b, 102c.

As shown in FIG. 5, the light emitting portion LE of the optical unit 102a is optically connected to the light source 106a of the measurement unit 106 by the optical fiber OF1 of the optical fiber cable 104a. With this configuration, light from the light source 106a is guided to the light emitting portion LE through the optical fiber OF1 and emitted from the light emitting portion LE. The light emitting portion LE has an optical system such as a lens (not shown) in order to emit the light guided to the light emitting portion LE through the optical fiber OF1 toward the wafer W as a light beam Bi. The optical element includes a light polarizer P that polarizes the light beam Bi emitted toward the wafer W into a linearly-polarized light beam. In addition, the light emitting portion LE has an angular adjuster (not shown) for adjusting an angle of the optical system in order to allow the linearly-polarized light beam Bi to be incident on the wafer W at a predetermined incident light.

On the other hand, the light detecting portion D of the optical unit 102a is optically connected to the spectroscope 106b of the measurement unit 106 by the optical fiber OF2 of the optical fiber cable 104a. The light detecting portion D is arranged in order to detect a reflected beam Br, which is a reflected light beam of the light beam Bi emitted toward the wafer W at a predetermined angle from the light emitting portion LE from an upper surface of the wafer W. For example, the light emitting portion LE and the light detecting portion D are arranged so that the light emitting portion LE and the light detecting portion D are inclined at equal angles with respect to a normal line of the wafer W, and so that the light beam Bi, the reflected beam Br, and the normal line form one plane. In addition, the light detecting portion D has a predetermined optical system in order to allow the reflected beam Br detected in such a manner to enter the optical fiber OF2. This optical system includes a photoelastic modulator PEM that polarizes the reflected beam Br into a circular polarized beam, and a light polarizer P. As stated, the optical units 102a through 102c are configured to include optical elements required for carrying out phase modulation ellipsometry.

The reflected beam Br detected by the light detecting portion D is guided to the spectroscope 106b through the optical fiber OF2. In the spectroscope 106b, the reflected beam Br (white light beam) is separated into spectral components that in turn are guided into the light detector 106c. The light detector 106c may include a photo-diode, a photomultiplier, or the like and outputs signals corresponding to a light intensity of the spectral components detected into the light detector 106c to the control unit 108. In addition, the control unit 108 outputs a control signal to the spectroscope 106b in order to drive the spectroscope 106b. With this, the control unit 108 can obtain a relationship between a wavelength (photon energy) of the light separated by the spectroscope 106b and the light intensity of the spectral components. The control unit 108 can obtain a film thickness of the film deposited on the wafer W, in accordance with the relationship between the wavelength and the light intensity and a predetermined algorithm.

Moreover, the control unit 108 can control an electric power source (not shown) for supplying electric power to the light source 106a of the measurement unit 106, and thus control the light source 106a by outputting a control signal to the electric power source. In addition, an optical system (not shown) for allowing the light from the light source 106a to enter the optical fiber OF1 is provided between the light source 106a and the optical fiber OF1. Moreover, a shutter (not shown) that opens and closes under control of the control unit 108 is arranged between the light source 106a and the optical fiber OF1, which makes it possible to emit the light beam Bi toward the wafer W at a predetermined timing and measure the film thickness of the film deposited on the wafer W at a predetermined timing.

Referring again to FIGS. 2 and 3, a reaction gas nozzle 31, a reaction gas nozzle 32, and separation gas nozzles 41, 42 are provided at predetermined angular intervals above the susceptor 2 and extend in the radial direction of the susceptor 2. The wafer receiving portion 24 can pass through and below the gas nozzles 31, 32, 41, and 42. In the illustrated example, the reaction gas nozzle 32, the separation gas nozzle 41, the reaction gas nozzle 31, and the separation gas nozzle 42 are arranged clockwise in this order. These nozzles 31, 32, 41, 42 penetrate the side wall portion of the chamber body 12 and are supported by attaching their base ends, which are gas inlet ports 31a, 32a, 41a, 42a, respectively, on the outer circumference of the wall portion. Although the gas nozzles 31, 32, 41, are introduced into the vacuum chamber 1 from the circumferential wall portion of the vacuum chamber 1 in the illustrated example, these gas nozzles 31, 32, 41, may be introduced from a ring-shaped protrusion portion 5 (described later). In this case, an L-shaped conduit may be provided in order to be open on the outer circumferential surface of the protrusion portion 5 and on the outer upper surface of the ceiling plate 11. With such an L-shaped conduit, the gas nozzle 31 (32, 41, 42) can be connected to one opening of the L-shaped conduit inside the vacuum chamber 1 and the gas inlet port 31a (32a, 41a, 42a) can be connected to the other opening of the L-shaped conduit outside the vacuum chamber 1.

Although not shown, the reaction gas nozzle is connected to a gas supplying source of bis (tertiary-butylamino) silane (BTBAS) gas, which is a first source gas, and the reaction gas nozzle 32 is connected to a gas supplying source of O₃ (ozone) gas, which is a second source gas, in this embodiment.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. An area below the reaction gas nozzle 31 may be called a process area P1 in which the BTBAS gas is adsorbed on the wafer W, and an area below the reaction gas nozzle 32 may be called a process area P2 in which the BTBAS gas adsorbed on the wafer W is oxidized by the O₃ gas.

On the other hand, the separation gas nozzles 41, 42 are connected to a gas supply source (not shown) of a separation gas. The separation gas may be nitrogen (N₂) gas, He gas, or an inert gas such as Ar gas, and is not limited to a particular gas, as long as the separation gas does not affect the deposition of a silicon oxide film using the BTBAS gas and the O₃ gas. In this embodiment, N₂ gas is used as the separation gas. The separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment.

The separation gas nozzles 41, 42 are provided in separation areas D configured to separate the process area P1 and the process area P2. In each of the separation areas D, a convex portion 4 is provided on the ceiling plate 11 of the vacuum chamber 1, as shown in FIGS. 2, 4, and the subsections (a) and (b) of FIG. 4. The convex portion 4 has a top view shape of a sector whose apex lies at the center of the vacuum chamber 1 and whose arced periphery lies near and along the inner circumferential wall of the chamber body 12. In addition, the convex portion 4 has a groove portion extending along the radial direction so that the groove portion 43 bisects the sector-shaped convex portion 4. The separation gas nozzle 41 (42) is housed in the groove portion 43. A circumferential distance between the center axis of the separation gas nozzle 41 (42) and one side of the sector-shaped convex portion 4 is substantially equal to the other circumferential distance between the center axis of the separation gas nozzle 41 (42) and the other side of the sector-shaped convex portion 4. Incidentally, while the groove portion 43 is formed in order to bisect the convex portion 4 in this embodiment, the groove portion 42 may be formed so that an upstream side of the convex portion 4 relative to the rotation direction of the susceptor 2 is wider, in other embodiments.

According to the above configuration, there are flat lower ceiling surfaces 44 (first ceiling surfaces) on both sides of the separation gas nozzle 41 (42), and higher ceiling surfaces 45 (second ceiling surfaces) outside of the corresponding lower ceiling surfaces 44, as shown in the subsection (a) of FIG. 4. The convex portion 4 (ceiling surface 44) provides a separation space, which is a thin space, in order to impede the first reaction gas and the second reaction gas from entering the space between the convex portion 4 and the susceptor 2.

Referring to the subsection (b) of FIG. 4, the O₃ gas flowing toward the convex portion 4 from the reaction gas nozzle 32 along the rotation direction of the susceptor 2 is impeded from entering the space between the convex portion 4 and the susceptor 2, and the BTBAS gas flowing toward the convex portion 4 from the reaction gas nozzle 31 along the counter-rotation direction of the susceptor 2 is impeded from entering the space between the convex portion 4 and the susceptor 2. “The gases being impeded from entering” means that the N₂ gas as the separation gas ejected from the separation gas nozzle 41 spreads between the ceiling surfaces 44 and the upper surface of the susceptor 2 and flows out to a space below the ceiling surfaces 45, which are adjacent to the corresponding ceiling surfaces 44 in the illustrated example, so that the gases cannot enter the separation space from the space below the ceiling surfaces 45. “The gases cannot enter the separation space” means not only that the gases are completely prevented from entering the separation space, but that the gases cannot proceed farther toward the separation gas nozzle 41 and thus be intermixed with each other even if a fraction of the reaction gases enters the separation space. Namely, as long as such an effect is demonstrated, the separation area D is to separate the process area P1 and the process area P2. Incidentally, the BTBAS gas or the O₃ gas adsorbed on the wafer W can pass through and below the convex portion 4. Therefore, the gases in “the gases being impeded from entering” mean the gases in a gaseous phase.

Referring to FIGS. 1, 2, and 3, an annular protrusion portion 5 is provided on the bottom surface of the ceiling plate 11. The protrusion portion 5 is arranged so that an inner circumferential surface of the protrusion portion 5 faces an outer circumferential surface of the core portion 21. The protrusion portion 5 opposes the susceptor 2 in an outer area of the core portion 21. In addition, the protrusion portion 5 is formed integrally with the convex portion 4, and a bottom surface of the protrusion portion 5 and a bottom surface of the convex portion 4 form one plane surface. In other words, a height of the bottom surface of the protrusion portion 5 from the susceptor 2 is equal to a height of the bottom surface (ceiling surface 44) of the ceiling plate 11. This height is referred to as h below. Incidentally, the convex portion 4 is formed not integrally with but separately from the protrusion portion 5 in other embodiments. FIGS. 2 and 3 show the inner configuration of the vacuum chamber 1 whose top plate 11 is removed while the convex portions 4 remain inside the vacuum chamber 1.

The separation area D is configured by forming the groove portion 43 in a sector-shaped plate to be the convex portion 4, and arranging the separation gas nozzle 41 (42) in the groove portion 43 in this embodiment. However, two sector-shaped plates may be attached on the bottom surface of the ceiling plate 11 by screws so that the two sector-shaped plates are located on both sides of the separation gas nozzle 41 (32).

In this embodiment, when the wafer W having a diameter of about 300 mm is supposed to be processed in the vacuum chamber 1, the convex portion 4 has a circumferential length of, for example, about 140 mm along an inner arc li (FIG. 3) that is at a distance 140 mm from the rotation center of the susceptor 2, and a circumferential length of, for example, about 502 mm along an outer arc lo (FIG. 3) corresponding to the outermost portion of the wafer receiving portions 24 of the susceptor 2. In addition, a circumferential length from one side wall of the convex portion 4 through the nearest side wall of the groove portion 43 along the outer arc lo is about 246 mm.

In addition, the height h (see the subsection (a) of FIG. 4) of the bottom surface of the convex portion 4, or the ceiling surface 44, measured from the upper surface of the susceptor 2 (or the wafer W) is, for example, about 0.5 mm through about 10 mm, and preferably about 4 mm. In this case, the rotational speed of the susceptor 2 is, for example, 1 through 500 revolutions per minute (rpm). In order to ascertain the separation function performed by the separation area D, the size of the convex portion 4 and the height h of the ceiling surface 44 from the susceptor 2 may be determined, depending on the pressure in the vacuum chamber 1 and the rotational speed of the susceptor 2, through experimentation.

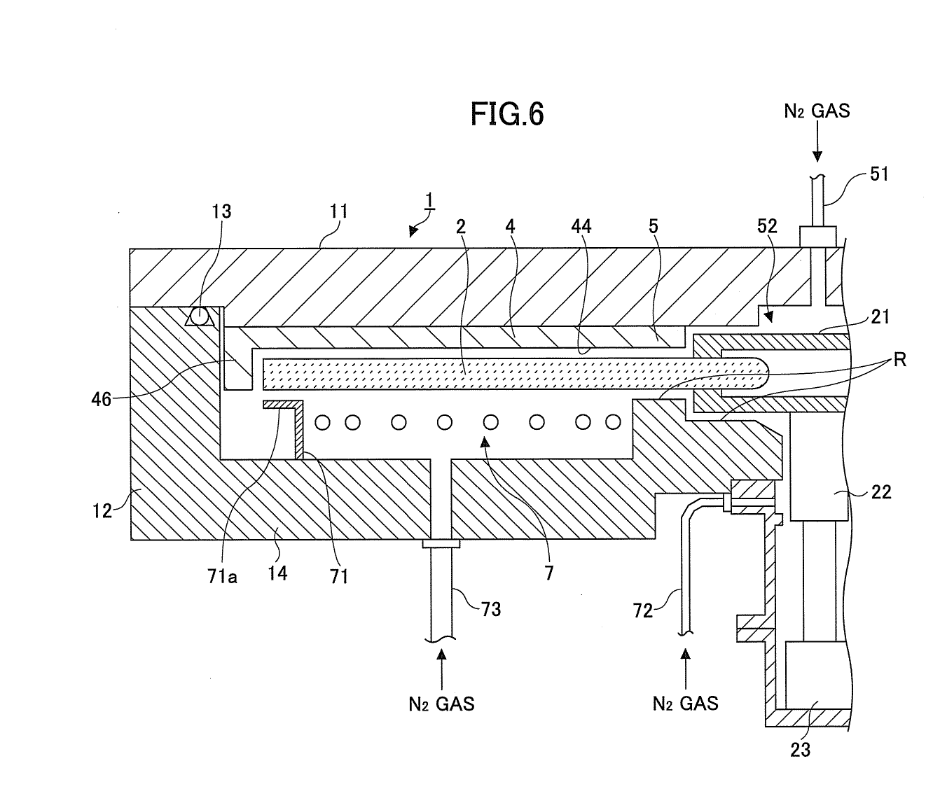

FIG. 6 shows a half portion of a cross-sectional view of the vacuum chamber 1, taken along line A-A in FIG. 3, where the convex portion 4 and the protrusion portion 5 formed integrally with the convex portion 4 are shown. As shown, the convex portion 4 has a bent portion 46 that bends in an L-shape at the outer circumferential edge of the convex portion 4. Although there are slight gaps between the bent portion 46 and the susceptor 2 and between the bent portion 46 and the chamber body 12 because the convex portion 4 is attached on the bottom surface of the ceiling portion 11 and removed from the chamber body 12 along with the ceiling portion 11, the bent portion 46 substantially fills out a space between the susceptor 2 and the chamber body 12, thereby preventing the first reaction gas (BTBAS) ejected from the first reaction gas nozzle 31 and the second reaction gas (ozone) ejected from the second reaction gas nozzle 32 from being intermixed through the space between the susceptor 2 and the chamber body 12. The gaps between the bent portion 46 and the susceptor 2 and between the bent portion 46 and the chamber body 12 may be the same as the height h of the ceiling surface 44 from the susceptor 2. In the illustrated example, a side wall facing the outer circumferential surface of the susceptor 2 serves as an inner circumferential wall of the separation area D.

Referring again to FIG. 1, which is a cross-sectional view taken along line B-B in FIG. 3, the chamber body 12 has an indented portion at the inner circumferential portion opposed to the outer circumferential surface of the susceptor 2. The indented portion is referred to as an evacuation area 6 hereinafter. Below the evacuation area 6, there is an evacuation port 61 (see FIG. 3 for another evacuation port 62) that is connected to a vacuum pump 64 via an evacuation pipe 63, which can also be used for the evacuation port 62. In addition, the evacuation pipe 63 is provided with a pressure controller 65. Plural pressure controllers 65 may be provided to the corresponding evacuation ports 61, 62.

Referring again to FIG. 3, the evacuation port 61 is located between the reaction gas nozzle 31 and the convex portion 4 that is located downstream relative to the rotation direction of the susceptor 2 in relation to the reaction gas nozzle 31, when viewed from above. With this configuration, the evacuation port 61 can substantially exclusively evacuate the BTBAS gas ejected from the reaction gas nozzle 31. On the other hand, the evacuation port 62 is located between the reaction gas nozzle 32 and the convex portion 4 that is located downstream relative to the rotation direction of the susceptor 2 in relation to the second reaction gas nozzle 32, when viewed from above. With this configuration, the evacuation port 62 can substantially exclusively evacuate the O₃ gas ejected from the reaction gas nozzle 32. Therefore, the evacuation ports 61, 62 so configured may assist the separation areas D to prevent the BTBAS gas and the O₃ gas from being intermixed.

Although the two evacuation ports 61, 62 are provided in the chamber body 12 in this embodiment, three evacuation ports may be provided in other embodiments. For example, an additional evacuation port may be provided in an area between the reaction gas nozzle 32 and the separation area D located upstream relative to the rotation of the susceptor 2 in relation to the reaction gas nozzle 32. In addition, another additional evacuation port may be made at a predetermined position in the chamber body 12. While the evacuation ports 61, 62 are located below the susceptor 2 to evacuate the vacuum chamber 1 through an area between the inner circumferential wall of the chamber body 12 and the outer circumferential surface of the susceptor 2 in the illustrated example, the evacuation ports may be located in the side wall of the chamber body 12. In addition, when the evacuation ports 61, 62 are provided in the side wall of the chamber body 12, the evacuation ports 61, 62 may be located higher than the susceptor 2. In this case, the gases flow along the upper surface of the susceptor 2 into the evacuation ports 61, 62 located higher the susceptor 2. Therefore, it is advantageous in that particles in the vacuum chamber 1 are not blown upward by the gases, compared to when the evacuation ports are provided, for example, in the ceiling plate 11.

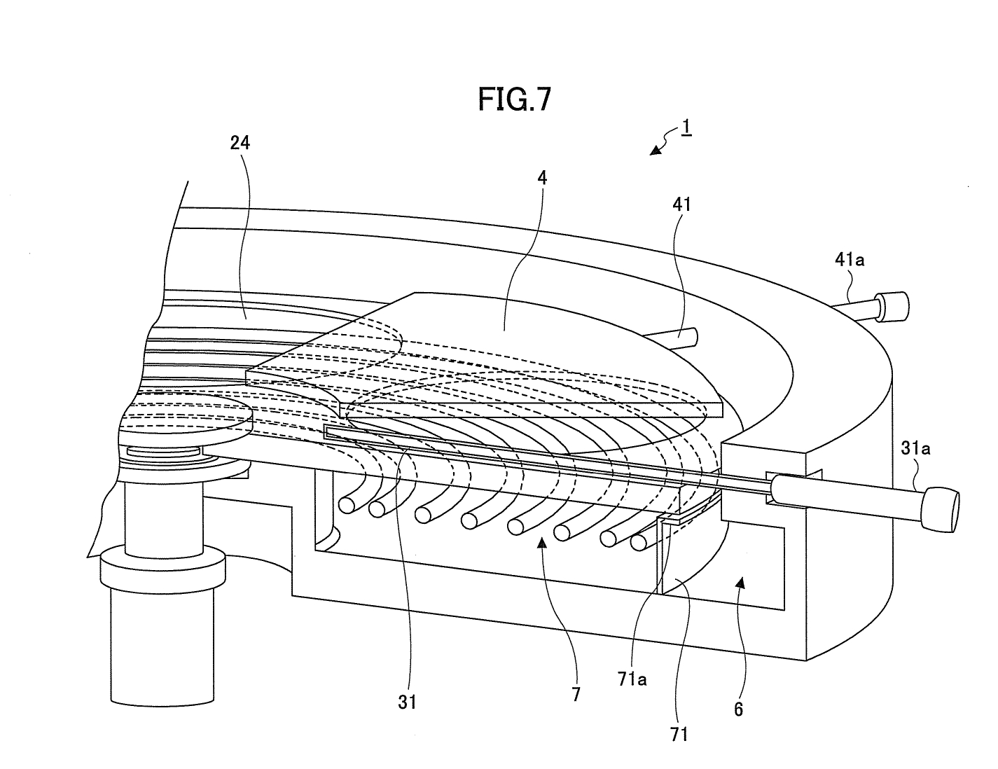

As shown in FIGS. 1, 2, and 7, a heater unit 7 composed of ring-shaped heater elements as a heating portion is provided in a space between the bottom portion 14 of the chamber body 12 and the susceptor 2, so that the wafers W placed on the susceptor 2 are heated through the susceptor 2 at a temperature determined by a process recipe. In addition, a cover member 71 is provided beneath the susceptor 2 and near the outer circumference of the susceptor 2 in order to surround the heater unit 7, so that the space where the heater unit 7 is located is partitioned from the outside area of the cover member 71. The cover member 71 has a flange portion 71a at the top. The flange portion 71a is arranged so that a slight gap is maintained between the bottom surface of the susceptor 2 and the flange portion in order to substantially prevent gas from flowing inside the cover member 71.

Referring to FIG. 6, the bottom portion 14 has a raised portion R inside of the heater unit 7. An upper surface of the raised portion R comes close to the susceptor 2 and the core portion 21, leaving slight gaps between the susceptor 2 and the upper surface of the raised portion R and between the upper surface of the raised portion R and the bottom surface of the core portion 21. In addition, the bottom portion 14 has a center hole through which the rotational shaft 22 passes. An inner diameter of the center hole is slightly larger than a diameter of the rotational shaft 22, leaving a gap for gaseous communication with the case body 20 through the flanged pipe portion 20a. A purge gas supplying pipe 72 is connected to an upper portion of the flange portion 20a. In addition, plural purge gas supplying pipes 73 are connected to areas below the heater unit 7 at predetermined angular intervals in order to purge the space where the heater unit 7 is housed (heater unit housing space).

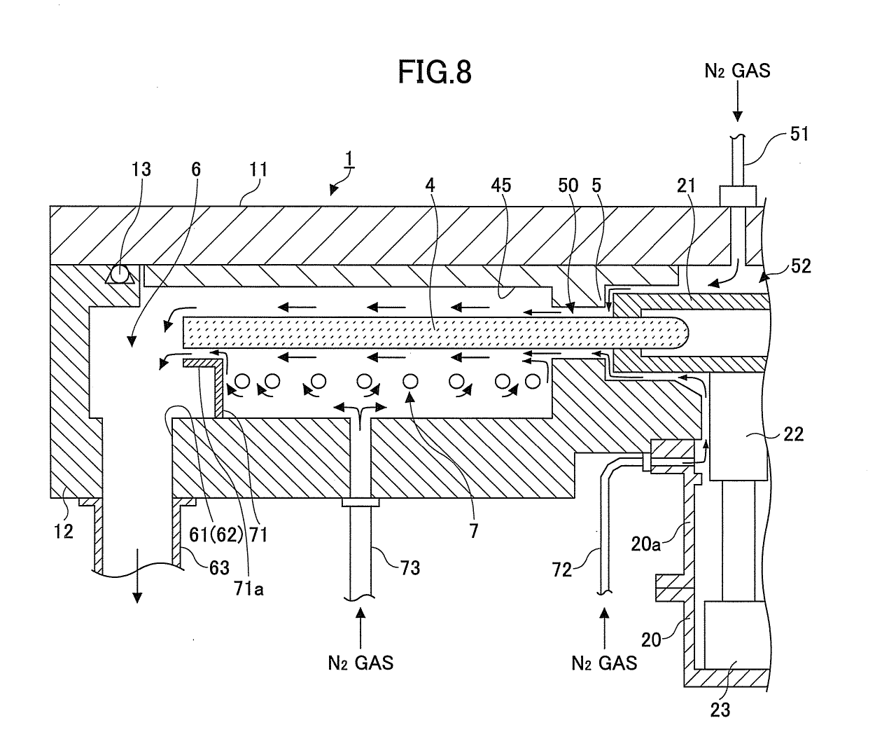

With such a configuration, N₂ purge gas flows from the purge gas supplying pipe 71 to the heater unit housing space through a gap between the rotational shaft 22 and the center hole of the bottom portion 14, a gap between the core portion 21 and the raised portion R of the bottom portion 14, and a gap between the bottom surface of the susceptor 2 and the raised portion R of the bottom portion 14. In addition, N₂ gas flows from the purge gas supplying pipes 73 to the heater unit housing space. Then, these N₂ gases flow into the evacuation port 61 through the gap between the flange portion 71a and the bottom surface of the susceptor 2. These flows of N₂ gas are illustrated by arrows in FIG. 8. The N₂ gases serve as separation gases that substantially prevent the BTBAS (O₃) gas from flowing around the space below the susceptor 2 to be intermixed with the O₃ (BTBAS) gas.

Referring to FIG. 8, a separation gas supplying pipe 51 is connected to a center portion of the ceiling plate 11 of the vacuum chamber 1. From the separation gas supplying pipe 51, N₂ gas as a separation gas is supplied to a space 52 between the ceiling plate 11 and the core portion 21. The separation gas supplied to the space 52 flows through a narrow gap 50 between the protrusion portion 5 and the susceptor 2 and along the upper surface of the susceptor 2 to reach the evacuation area 6. Because the space 52 and the gap 50 are filled with the separation gas, the BTBAS gas and the O₃ gas are not intermixed through the center portion of the susceptor 2. In other words, the film deposition apparatus 200 according to this embodiment is provided with a center area C defined by a rotational center portion of the susceptor 2 and the vacuum chamber 1 and configured to have an ejection opening for ejecting the separation gas toward the upper surface of the susceptor in order to separate the process area P1 and the process area P2. In the illustrated example, the ejection opening corresponds to the gap 50 between the protrusion portion 5 and the susceptor 2.

In addition, the film deposition apparatus 200 according to this embodiment is provided with a control portion 100 for substantially entirely controlling the film deposition apparatus 200. The control portion 100 includes a process controller 100a composed of, for example, a computer, a user interface portion 100b, and a memory device 100c. The user interface portion 100b includes a display that displays a process, and a keyboard or a touch panel (not shown) by which an operator of the film deposition apparatus 200 chooses a process recipe, a process manager changes process parameters of the process recipe, and the like.

The memory device 100c stores control programs or process recipes for causing the process controller 100a to carry out various processes, and process parameters for various processes. In addition, these programs or recipes have a group of steps for causing the film deposition apparatus 200 to carry out, for example, an operation (a film deposition method, which includes film thickness measurement) described later. These control programs or process recipes are read out by the process controller 100a by an instruction from the user interface portion 100b. Moreover, these programs or recipes may be stored in a computer readable storage medium 100d, and installed into the memory device 100c through an input/output (I/O) device (not shown). The computer readable storage medium may be a hard disk, a compact disk (CD), a CD-readable, a CD-rewritable, a digital versatile disk (DVD)-rewritable, a flexible disk, a semiconductor memory, or the like. Additionally, the programs or recipes may be downloaded to the memory device 100c through a communication line.

Next, an operation (film deposition method) of the film deposition apparatus 200 according to this embodiment is explained.

(Wafer Transfer-in Process)

A wafer transfer-in process where the wafer W is placed on the susceptor 2 is explained with reference to the previously referred drawings. First, one of the wafer receiving portions 24 is aligned with the transfer opening 15 by rotating the susceptor 2, and the gate valve (not shown) is opened. Next, the wafer W is transferred into the vacuum chamber 1 by the transfer arm 10 through the transfer opening 15, and held above the wafer receiving portion 24. Then, the lift pins 16 are raised to receive the wafer W from the transfer arm 10, and the transfer arm 10 retracts from the vacuum chamber 1. After the gate valve (not shown) is closed, the lift pins 16 are brought down so that the wafer W is placed in the wafer receiving portion 24 of the susceptor 2.

After this series of procedures are repeated the same number of times as the number of the wafers W to be processed in one run, the wafer transfer-in process is completed.

(Film Deposition Process)

After the wafers W are transferred in, the vacuum chamber 1 is evacuated to a predetermined pressure by the vacuum pump 64 (FIG. 1). Then, the susceptor 2 begins rotating clockwise, as seen from above. The susceptor 2 is heated to a predetermined temperature (for example, 300° C.) by the heater unit 7 in advance, and the wafers W can also be heated at substantially the same temperature by being placed on the susceptor 2. After the wafers W are heated and maintained at the predetermined temperature, N₂ gas is supplied from the separation gas nozzles 41, 42; the BTBAS gas is supplied to the process area P1 through the reaction gas nozzle 31; and the O₃ gas is supplied to the process area P2 through the reaction gas nozzle 32.

When the wafer W passes through the process area P1 below the reaction gas nozzle 31, BTBAS molecules are adsorbed on an upper surface of the wafer W; and when the wafer W passes through the process area P2 below the reaction gas nozzle 32, O₃ molecules are adsorbed on an upper surface of the wafer W and oxidize the BTBAS molecules. Therefore, when the wafer W passes the process areas P1, P2 one time due to the rotation of the susceptor 2, one molecular layer of silicon oxide is produced on the upper surface of the wafer W.

(Film Thickness Measurement)

While film deposition occurs in the above manner, a film thickness is measured as follows.

First, measurement timing is determined in accordance with a rotational speed of the susceptor 2. The measurement timing may be determined, in the following manner. A magnet is attached at, for example, a predetermined position, which may correspond to the wafer receiving portion 24 of the susceptor 2, on the outer circumferential surface of the rotational shaft 22, and a periodic change in magnetic intensity caused by the rotation of the rotational shaft 22 is measured by a magnetic head.

Next, the control unit 108 (FIGS. 1 and 5) controls the power source of the light source 106a to turn on the light source 106a, and opens/closes the shutter (not shown) in accordance with the determined measurement timing, in order to cause the light from the light source 106a to enter the optical fiber OF1 in pulses. With this, the pulsed light is irradiated onto the wafer W subject to the film thickness measurement. Namely, the light from the light source 106a reaches the light emitting portion LE in pulses through the optical fiber OF1, is emitted as the light beam Bi from the light emitting portion LE, and is selectively irradiated onto the wafer W subject to the film thickness measurement on the susceptor 2. Then, the reflection beam Br reflected by the wafer W enters the light detecting portion D and reaches the spectroscope 106b through the optical fiber OF2. At this time, the spectroscope 106b is controlled by the control unit 108 to scan wavelengths from about 240 nm through about 827 nm (about 1.5 eV through about 5 eV in photon energy) while the reflection beam Br from the wafer W is emitted from the optical fiber OF2. Specifically, the control unit 108 transmits to the spectroscope 106b a control signal in synchronization with a signal for controlling the opening/closing of shutter, and the spectroscope 106b carries out wavelength scanning in accordance with the control signal. In such a manner, a spectroscopic measurement is carried out when the pulsed light beam Bi is irradiated onto the wafer W, and thus data on a dependence of the light intensity of the reflection beam Br on the wavelength (photon energy) are obtained.

Next, the control unit 108 calculates a thickness of the film deposited on the wafer W in accordance with the data on the dependence of the light intensity of the reflection beam Br on the wavelength (photon energy) by employing a predetermined algorithm. Then, the control unit 108 compares the calculated film thickness of the film with a target film thickness, which may be obtained by referring to the process recipe downloaded to the control portion 100 of the film deposition apparatus 200 every time the comparison is carried out. Alternatively, the target thickness may be received by the control unit 108 from the control portion 100 and stored in advance in the control unit 108. As a result of the comparison, when it is determined that the calculated film thickness is greater than or equal to the target thickness, the control unit 108 outputs a notification signal to the control portion 100 in order to cause the film deposition to stop the film deposition. Upon receiving the notification signal, the control portion 100 stops supplying the BTBAS gas, the O₃ gas, and the N₂ gas and rotating the susceptor 2, and starts the following wafer transfer-out process.

Incidentally, the film thickness measurement can be simultaneously carried out at plural positions corresponding to the optical units 102a through 102c, which makes it possible to measure the thickness at three measurement points. In this case, because the film deposition may be stopped when the thicknesses at all the three points become greater than or equal to the target thickness, or when the thickness at one of the three points becomes greater than or equal to, or the thicknesses at two points become greater than or equal to the target thickness. Moreover, the film thickness measurement may be carried out with respect to one wafer W placed in a predetermined wafer receiving portion 24, or all the wafers W on the susceptor 2.

In addition, duration of the pulsed light beam Bi irradiated onto the wafer W is determined depending on, for example, the rotational speed of the susceptor 2. Specifically, the duration (period when the shutter is opened) of the light beam Bi may be about 10 ms through about 100 ms. Moreover, the thickness is not necessarily measured every rotation of the susceptor 2, but may be measured every 5 through 20 rotations of the susceptor 2.

(Wafer Transfer-Out Process)

After the film deposition process, the vacuum chamber 1 is purged. Then, the wafers W are transferred out one by one in accordance with procedures opposite to those in the wafer transfer-in process. Namely, after the wafer receiving portion 24 is in alignment with the transfer opening 15 and the gate valve is opened, the lift pins 16 are raised to hold the wafer W above the susceptor 2. Next, the transfer arm 10 proceeds below the wafer W, and receives the wafer W when the lift pins 16 are brought down. Then, the transfer arm 10 retracts from the vacuum chamber 1, so that the wafer W is transferred out from the vacuum chamber 1. With these procedures, one wafer W is transferred out. Subsequently, the procedures are repeated until all the wafers W are transferred out.

Advantages of the film deposition method using the film deposition apparatus according to this embodiment are explained in the following.

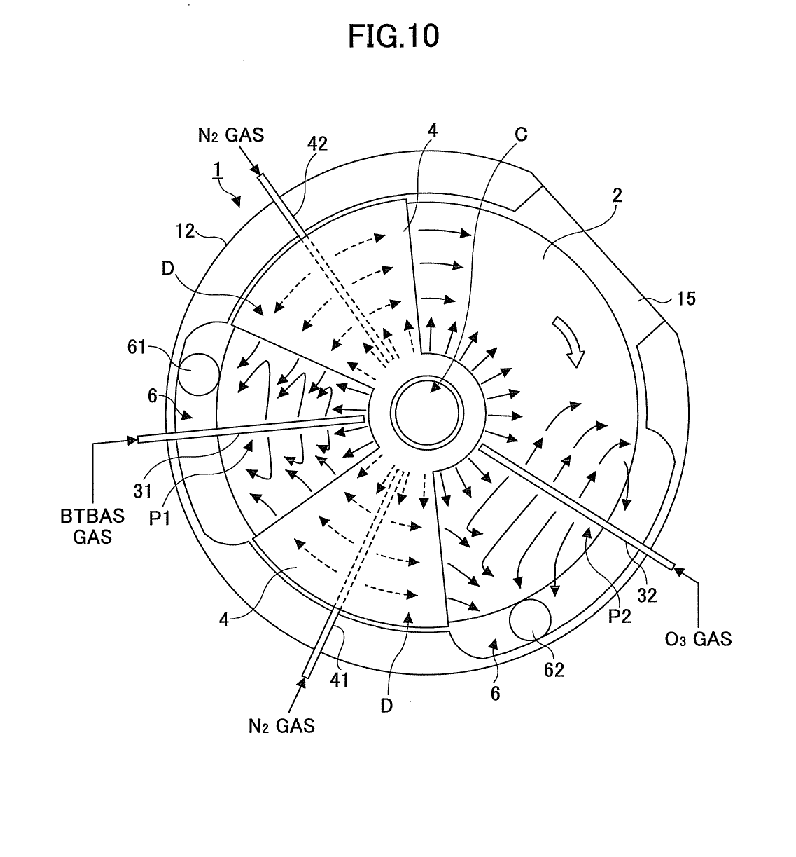

FIG. 10 schematically illustrates the flow patterns of the gases supplied into the chamber 1 from the gas nozzles 31, 32, 41, 42. As shown, part of the O₃ gas ejected from the second reaction gas nozzle 32 hits and flows along the top surface of the susceptor 2 (and the surface of the wafer W) in a direction opposite to the rotation direction of the susceptor 2. Then, the O₃ gas is pushed back by the N₂ gas flowing along the rotation direction, and changes the flow direction toward the edge of the susceptor 2 and the inner circumferential wall of the chamber body 12. Finally, this part of the O₃ gas flows into the evacuation area 6 and is evacuated from the chamber 1 through the evacuation port 62.

Another part of the O₃ gas ejected from the second reaction gas nozzle 32 hits and flows along the top surface of the susceptor 2 (and the surface of the wafers W) in the same direction as the rotation direction of the susceptor 2. This part of the O₃ gas mainly flows toward the evacuation area 6 due to the N₂ gas flowing from the center portion C and suction force through the evacuation port 62. On the other hand, a small portion of this part of the O₃ gas flows toward the separation area located downstream of the rotation direction of the susceptor 2 in relation to the second reaction gas nozzle 32 and may enter the gap between the ceiling surface 44 and the susceptor 2. However, because the height h of the gap is designed so that the gas is impeded from flowing into the gap at film deposition conditions intended, the small portion of the gas cannot flow into the gap. Even if a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the top surface of the susceptor 2 in the rotation direction flows into the evacuation area 6 and is evacuated by the evacuation port 62, as shown in FIG. 10.

Similarly, part of the BTBAS gas ejected from the first reaction gas nozzle 31 to flow along the top surface of the susceptor 2 (and the surface of the wafers W) in a direction opposite to the rotation direction of the susceptor 2 is prevented from flowing into the gap between the susceptor 2 and the ceiling surface 44 of the convex portion 4 located upstream relative to the rotation direction of the susceptor 2 in relation to the first reaction gas supplying nozzle 31. Even if only a fraction of the BTBAS gas flows into the gap, this BTBAS gas is pushed backward by the N₂ gas ejected from the separation gas nozzle 41 in the separation area D. The BTBAS gas pushed backward flows toward the outer circumferential edge of the susceptor 2 and the inner circumferential wall of the chamber body 12, along with the N₂ gases from the separation gas nozzle 41 and the center portion C, and then is evacuated by the evacuation port 61 through the evacuation area 6.

Another part of the BTBAS gas ejected from the first reaction gas nozzle 31 to flow along the top surface of the susceptor 2 (and the surface of the wafers W) in the same direction as the rotation direction of the susceptor 2 cannot flow into the gap between the susceptor 2 and the ceiling surface 44 of the convex portion 4 located downstream relative to the rotation direction of the susceptor 2 in relation to the first reaction gas supplying nozzle 31. Even if a fraction of this part of the BTBAS gas flows into the gap, this BTBAS gas is pushed backward by the N₂ gases ejected from the center portion C and the separation gas nozzle 42 in the separation area D. The BTBAS gas pushed backward flows toward the evacuation area 6, along with the N₂ gases from the separation gas nozzle 41 and the center portion C, and then is evacuated by the evacuation port 61.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. The BTBAS molecules and the O₃ molecules adsorbed on the wafer W are allowed to go through the separation area D, contributing to the film deposition.

Additionally, the BTBAS gas in the process area P1 (the O₃ gas in the process area P2) is prevented from flowing into the center area C, because the separation gas is ejected toward the outer circumferential edge of the susceptor 2 from the center area C, as shown in FIGS. 8 and 10. Even if a fraction of the BTBAS gas in the process area P1 (the O₃ gas in the process area P2) flows into the center area C, the BTBAS gas (the O₃ gas) is pushed backward, so that the BTBAS gas in the process area P1 (the O₃ gas in the process area P2) is prevented from flowing into the process area P2 (the process area P1) through the center area C.

Moreover, the BTBAS gas in the process area P1 (the O₃ gas in the process area P2) is prevented from flowing into the process area P2 (the process area P1) through the space between the susceptor 2 and the inner circumferential wall of the chamber body 12. This is because the bent portion 46 is formed downward from the convex portion 4 so that the gaps between the bent portion 46 and the susceptor 2 and between the bent portion 46 and the inner circumferential wall of the chamber body 12 are as small as the height h of the ceiling surface 44 of the convex portion 4, the height h being measured from the susceptor 2, thereby substantially avoiding pressure communication between the two process areas, as stated above. Therefore, the BTBAS gas is evacuated from the evacuation port 61, and the O₃ gas is evacuated from the evacuation port 62, and thus the two reaction gases are not mixed. In addition, the space (heater unit housing space) below the susceptor 2 is purged by the N₂ gas supplied from the purge gas supplying pipes 72, 73. Therefore, the BTBAS gas cannot flow through below the susceptor 2 into the process area P2.

Incidentally, during the film deposition process, the N₂ gas as the separation gas is also supplied from the separation gas supplying pipe 51, and thus the N₂ gas is ejected toward the upper surface of the susceptor 2 from the center area C, namely the space 50 between the protrusion portion 5 and the susceptor 2. In this embodiment, a space that is below the higher ceiling surface 45 and in which the reaction gas nozzle 31 (32) is arranged has a lower pressure than that in the thin space between the lower ceiling surface 44 and the susceptor 2. This is partly because the evacuation area 6 is provided adjacent to the space below the ceiling surface 45, and the space is evacuated directly through the evacuation area 6, and partly because the height h of the thin space is designed to maintain the pressure difference between the thin space and the space where the reaction gas nozzle 31 (32) is arranged.

As stated above, because the two source gases (BTBAS gas, O₃ gas) are substantially prevented from being intermixed in the vacuum chamber 1 in the film deposition apparatus 200 according to this embodiment, a substantially realistic ALD can be realized, thereby providing excellent film thickness controllability. In addition, because the film deposition apparatus is provided with the film thickness measurement system 101, more excellent film thickness controllability can be obtained. Namely, according to the film thickness measurement system 101, the film thickness can be monitored during the film deposition and the film deposition can be terminated when the film thickness reaches the target thickness. Therefore, the target thickness can be assuredly obtained. Therefore, when the film deposition apparatus 200 according to this embodiment is employed in semiconductor device fabrication, a device performance can be assuredly demonstrated, and a production yield can be improved.

In addition, while a test run is usually carried out prior to a production run to find out suitable deposition conditions in order to realize the target thickness, the film deposition apparatus 200 according to this embodiment may eliminate the necessity of such a test run. Therefore, the production cost can be reduced by a cost required to carry out the test run. Moreover, because a production run can be carried out in a time spent for carrying out the test run, an increased number of production runs can be carried out. Furthermore, because the test run is not necessary, maintenance frequency can be reduced.

In addition, because the film thickness measurement system 101 in this embodiment is configured as an ellipsometer, the film thickness can be measured in a very short period of about 10 ms through about 100 ms. Therefore, even when the susceptor 2 is rotated, the film thickness can be measured at tiny spots on the wafer W placed on the susceptor 2. Incidentally, the film thickness can be measured at plural points over the upper surface of the wafer W using only one optical unit 102a. When the film thickness is measured at plural points over the upper surface of the wafer W using three optical units 102a through 102c, a film thickness variation over the wafer W can be obtained.

Furthermore, because the film thickness measurement system 101 according to this embodiment is configured as an ellipsometer, a thickness of each layer in a multi-layered film composed of plural materials deposited layer-by-layer can be measured. For example, when a silicon oxide layer/a silicon nitride layer/a silicon oxide layer (ONO film) are continuously deposited in the film deposition apparatus 200, the thickness of each layer can be measured. In addition, when a strontium titanate (SrTiO) is realized as a multi-layered film of a titanium oxide (TiO) layer and a strontium oxide (SrO) layer, the thicknesses of the TiO layer and the SrO layer can be measured.

In addition, because the two source gases are effectively impeded from being intermixed in the vacuum chamber 1, the film deposition occurs substantially exclusively on the wafers W and the susceptor 2. Therefore, almost no films are deposited on the transparent window 201, and thus maintenance frequency can be reduced. Namely, downtime of the film deposition apparatus 200, which is required due to the film thickness measurement system 101, is scarcely increased.

An example of process parameters preferable in the film deposition apparatus 200 according to this embodiment is listed below.

rotational speed of the susceptor 2: 1-500 rpm (in the case of the wafer W having a diameter of 300 mm)

pressure in the chamber 1: 1067 Pa (8 Torr)

wafer temperature: 350° C.

flow rate of BTBAS gas: 100 sccm

flow rate of O₃ gas: 10000 sccm

flow rate of N₂ gas from the separation gas nozzles 41, 42: 20000 sccm

flow rate of N₂ gas from the separation gas supplying pipe 51: 5000 sccm

the number of rotations of the susceptor 2: 600 rotations (depending on the film thickness required)

According to the film deposition apparatus 200 of this embodiment, because the film deposition apparatus 200 is provided with the separation areas including the lower ceiling plates 44, between the process area P1 where the BTBAS gas is supplied and the process area P2 where the O₃ gas is supplied, the BTBAS gas (O₃ gas) is impeded from flowing into the process area P1 (22) and being intermixed with the O₃ gas (BTBAS gas). Therefore, the ALD mode deposition of the silicon oxide film can be assuredly carried out by rotating the susceptor 2 on which the wafers W are placed in order for the wafers W to pass through the process area P1, the separation area D, the process area P2, and the separation area D. In addition, the separation areas D include the corresponding separation gas nozzles 41, 42 that eject N₂ gas in order to assuredly impede the BTBAS gas (O₃ gas) from flowing into the process area P2 (P1) and thus being intermixed with the O₃ gas (BTBAS gas). Moreover, because the vacuum chamber 1 of the film deposition apparatus 200 according to this embodiment includes the center area C having the ejection opening from which the N₂ gas is ejected, the BTBAS gas (O₃ gas) can be impeded from flowing into the process area 22 (P1) through the center area C and thus being intermixed with the O₃ gas (BTBAS gas). Furthermore, because the BTBAS gas and the O₃ gas are scarcely intermixed, only a thin silicon oxide film is deposited on the susceptor 2, thereby reducing a particle problem.

Incidentally, while five wafers W placed in the corresponding wafer receiving portions 24 can be processed in one run because the susceptor 2 has the five wafer receiving portions 24 in the film deposition apparatus 200 according to this embodiment, only one wafer W may be placed in one wafer receiving portion 24, or only one wafer receiving portion 24 may be made in the susceptor 2.

In addition, not being limited to ALD of a silicon oxide film, the film deposition apparatus 200 may be used to carry out ALD of a silicon nitride film. As a nitriding gas in the case of ALD of silicon nitride, ammonia (NH₃), hydrazine (N₂H₂), and the like are used.

Moreover, as a source gas for the silicon oxide or nitride film deposition, dichlorosilane (DCS), hexadichlorosilane (HCD, tris(dimethylamino)silane (3DMAS), tetra ethyl ortho silicate (TEOS), and the like may be used rather than BTBAS.

Moreover, the film deposition apparatus according to an embodiment of the present invention may be used for MLD of an aluminum oxide (Al₂O₃) film using trymethylaluminum (TMA) and O₃ or oxygen plasma, a zirconium oxide (ZrO₂) film using tetrakis(ethylmethylamino)zirconium (TEMAZ) and O₃ or oxygen plasma, a hafnium oxide (HfO₂) film using tetrakis(ethylmethylamino)hafnium (TEMAHf) and O₃ or oxygen plasma, a strontium oxide (SrO) film using bis(tetra methyl heptandionate) strontium (Sr(THD)₂) and O₃ or oxygen plasma, a titanium oxide (TiO) film using (methyl-pentadionate)(bis-tetra-methyl-heptandionate) titanium (Ti(MPD)(THD)) and O₃ or oxygen plasma, and the like, rather than the silicon oxide film and the silicon nitride film.

Because a larger centrifugal force is applied to the gases in the vacuum chamber 1 at a position closer to the outer circumference of the susceptor 2, the BTBAS gas, for example, flows toward the separation area D at a higher speed in the position closer to the outer circumference of the susceptor 2. Therefore, the BTBAS gas is more likely to enter the gap between the ceiling surface 44 and the susceptor 2 in the position closer to the circumference of the susceptor 2. Because of this situation, when the convex portion 4 has a greater width (a longer arc) toward the circumference, the BTBAS gas cannot flow farther into the gap in order to be intermixed with the O₃ gas. In view of this, it is preferable for the convex portion 4 to have a sector-shaped top view, as explained above.

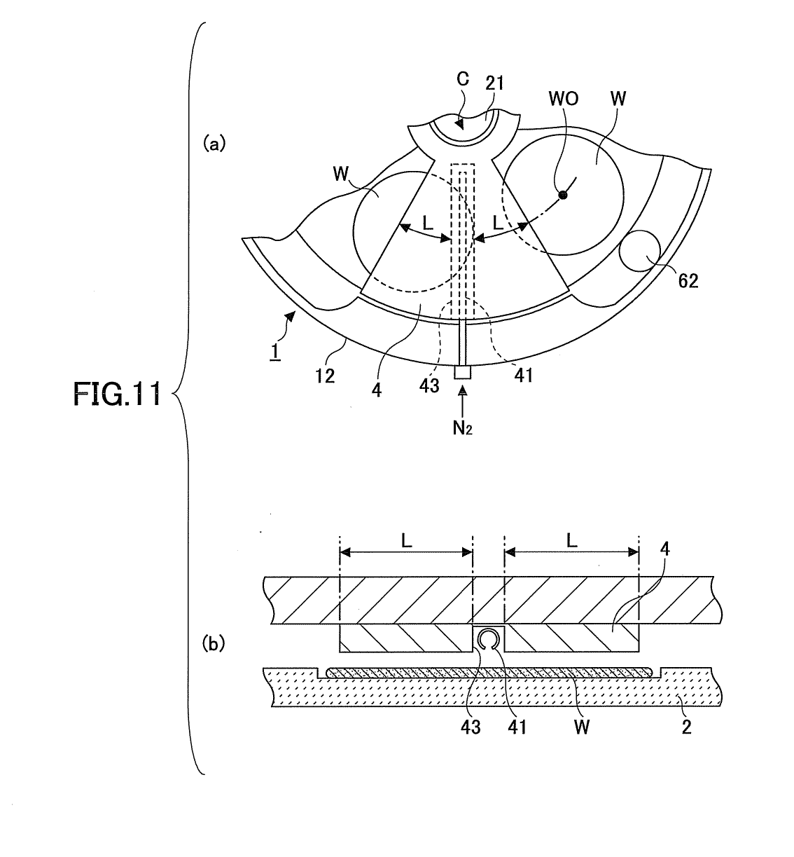

The size of the convex portion 4 (or the ceiling surface 44) is exemplified again below. Referring to subsections (a) and (b) of FIG. 11, the ceiling surface 44 that creates the thin space on both sides of the separation gas nozzle 41 (42) may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the susceptor 2 (wafer W) has to be accordingly small in order to effectively impede the reaction gases from flowing into the thin space. However, when the length L becomes too small and thus the height h has to be extremely small, the susceptor 2 may hit the ceiling surface 44, which may cause wafer breakage and wafer contamination through particle generation. Therefore, measures to dampen vibration of the susceptor 2 or measures to stably rotate the susceptor 2 are required in order to avoid the susceptor 2 hitting the ceiling surface 44. On the other hand, when the height h of the thin space is kept relatively greater while the length L is small, a rotational speed of the susceptor 2 has to be lower in order to avoid the reaction gases flowing into the thin gap between the ceiling surface 44 and the susceptor 2, which is rather disadvantageous in terms of production throughput. From these considerations, the length L of the ceiling surface 44 along the arc corresponding to the route of the wafer center WO is preferably about 50 mm or more. However, the size of the convex portion 4 or the ceiling surface 44 is not limited to the above size, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used.

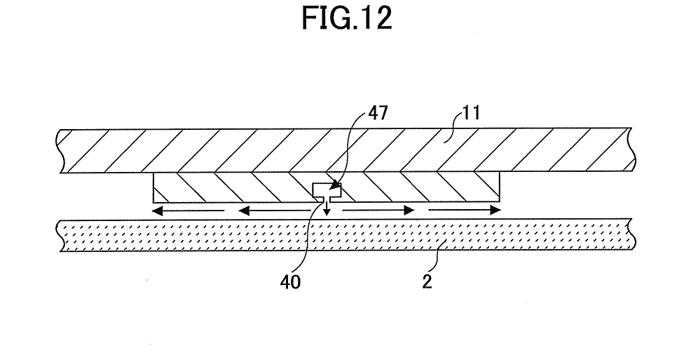

In addition, the separation gas nozzle 41 (42) is housed in the groove portion 43 made in the convex portion 4, which provides the lower ceiling surfaces 44 on both sides of the separation gas nozzle 41 (42) in the above embodiment. However, as shown in FIG. 12, a conduit 47 extending along the radial direction of the susceptor 2 may be made inside the convex portion 4, instead of the separation gas nozzle (42), and plural holes 40 may be formed along the longitudinal direction of the conduit 47 so that the N₂ gas as the separation gas may be ejected from the plural holes 40 in other embodiments.

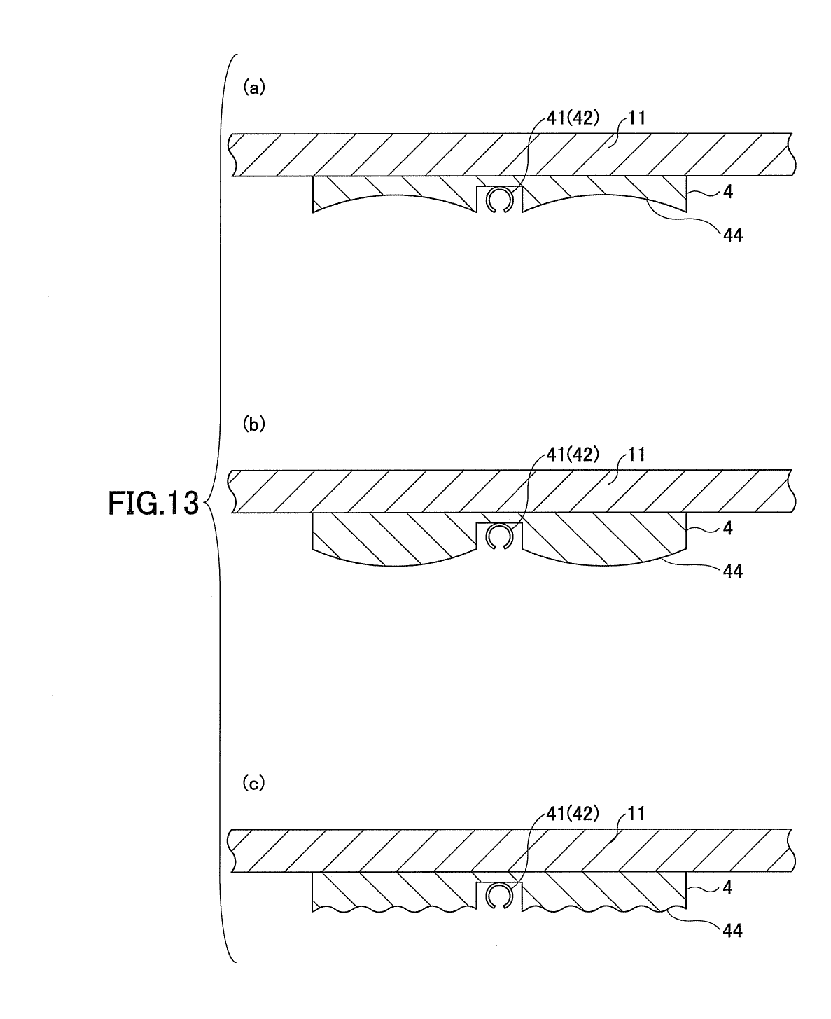

The ceiling surface 44 of the separation area D may have a concavely curved surface shown in a subsection (a) of FIG. 13, a convexly curved surface shown in a subsection (b) of FIG. 13, or a corrugated surface shown in a subsection (c) of FIG. 13, not being limited to the flat surface.

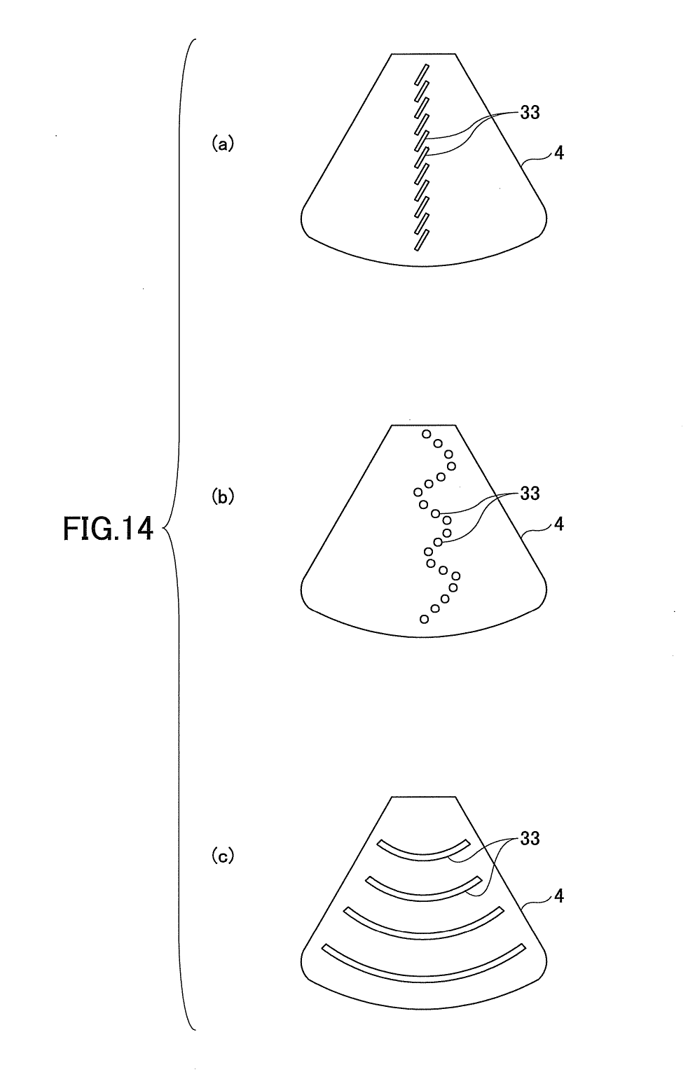

Moreover, the convex portion 4 may be hollow, and the separation gas may be introduced into the hollow space. In this case, plural gas ejection holes 33 may be arranged as shown in subsections (a) through (c) of FIG. 14.

Referring to the subsection (a) of FIG. 14, each of the plural gas ejection holes 33 has a shape of a slanted slit. These slanted slits (gas ejection holes 33) are arranged to be partially overlapped with an adjacent slit along the radial direction of the susceptor 2. In the subsection (b) of FIG. 14, each of the plural gas ejection holes 33 has a circular shape. These circular holes (gas ejection holes 33) are arranged along a serpentine line that extends in the radial direction as a whole. In the subsection (c) of FIG. 14, each of the plural gas ejection holes 33 has a shape of an arc-shaped slit. These arc-shaped slits (gas ejection holes 33) are arranged at predetermined intervals in the radial direction of the susceptor 2.

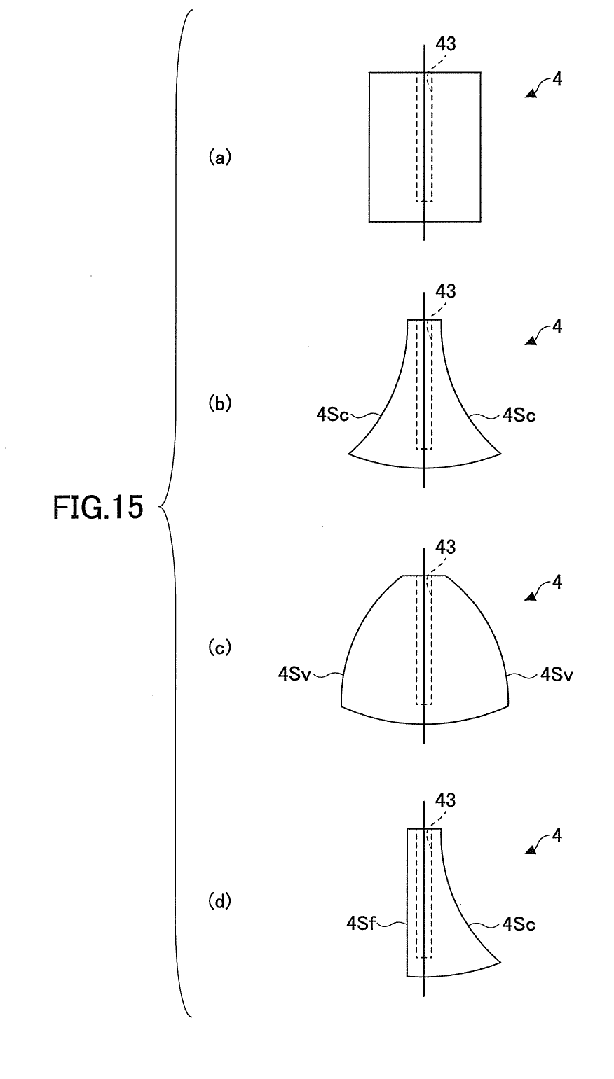

While the convex portion 4 has the sector-shaped top view shape in this embodiment, the convex portion 4 may have a rectangle top view shape as shown in a subsection (a) of FIG. 15, or a square top view shape in other embodiments. Alternatively, the convex portion 4 may be sector-shaped as a whole in the top view and have concavely curved side surfaces 4Sc, as shown in a subsection (b) of FIG. 15. In addition, the convex portion 4 may be sector-shaped as a whole in the top view and have convexly curved side surfaces 4Sv, as shown in a subsection (c) of FIG. 15. Moreover, an upstream portion of the convex portion 4 relative to the rotation direction of the susceptor 2 (FIG. 1) may have a concavely curved side surface 4Sc and a downstream portion of the convex portion 4 relative to the rotation direction of the susceptor 2 (FIG. 1) may have a flat side surface 4Sf, as shown in a subsection (d) of FIG. 15. Incidentally, dotted lines in the subsections (a) through (d) of FIG. 15 represent the groove portions 43. In these cases, the separation gas nozzle 41 (42) (FIG. 2), which is housed in the groove portion 43 (the subsections (a) and (b) of FIG. 4), extends from the center portion of the vacuum chamber 1, for example, from the protrusion portion 5 (FIG. 1).

The heater unit 7 for heating the wafer W may be configured by a heating lamp, instead of a resistive heating element. In addition, the heater unit may be arranged above the susceptor 2 rather than below the susceptor 2, or both above and below the susceptor 2.

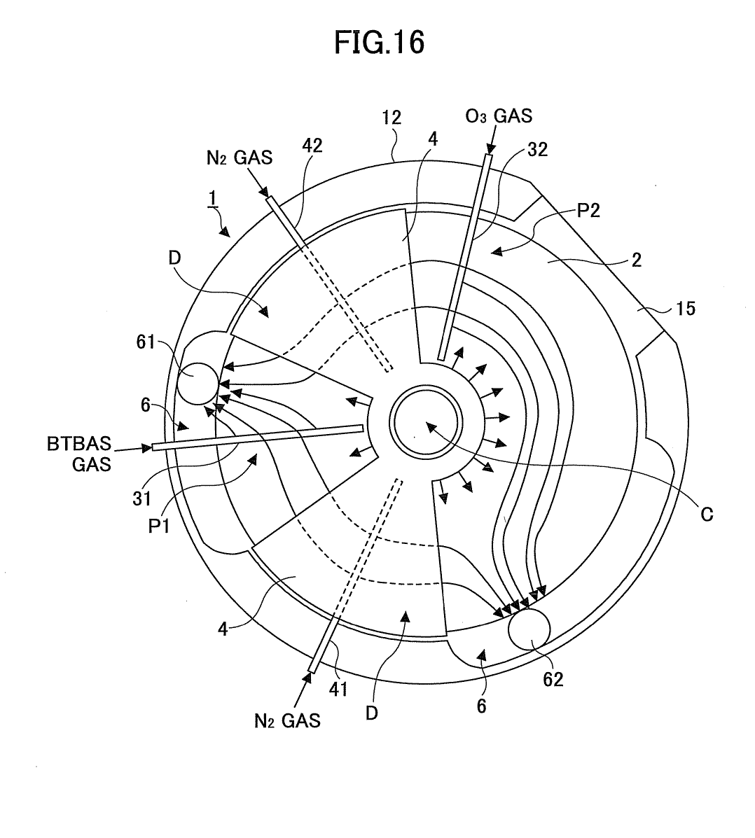

The process areas P1, P2 and the separation areas D may be arranged, for example, as shown in FIG. 16 in other embodiments. Referring to FIG. 16, the reaction gas nozzle 32 for supplying, for example, the O₃ gas is arranged upstream in the rotation direction of the susceptor 2 relative to the transfer opening 15, or between the separation gas nozzle 42 and the transfer opening 15. Even in such an arrangement, the gases ejected from the nozzles and the center area C flow substantially as shown by arrows in FIG. 16, and thus the reaction gases are impeded from being intermixed. Therefore, an appropriate ALD can be realized in such an arrangement.

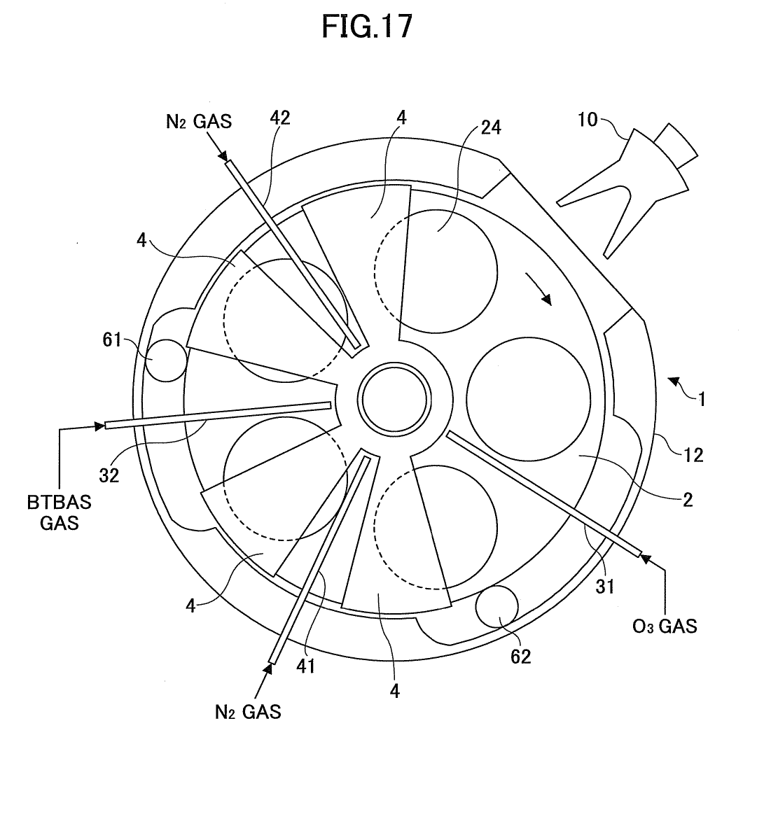

In addition, the separation area D may be configured by attaching two sector-shaped plates on both sides of the separation gas nozzle 41 (42) on the bottom surface of the ceiling plate 11 with screws. Such a configuration is illustrated in FIG. 17. In this case, a distance between the convex portion 4 and the separation gas nozzle 41 (42) and a size of the convex portion 4 may be determined by taking into consideration an ejection rate of the separation gas and the reaction gases in order to efficiently demonstrate the separation effect by the separation areas D.

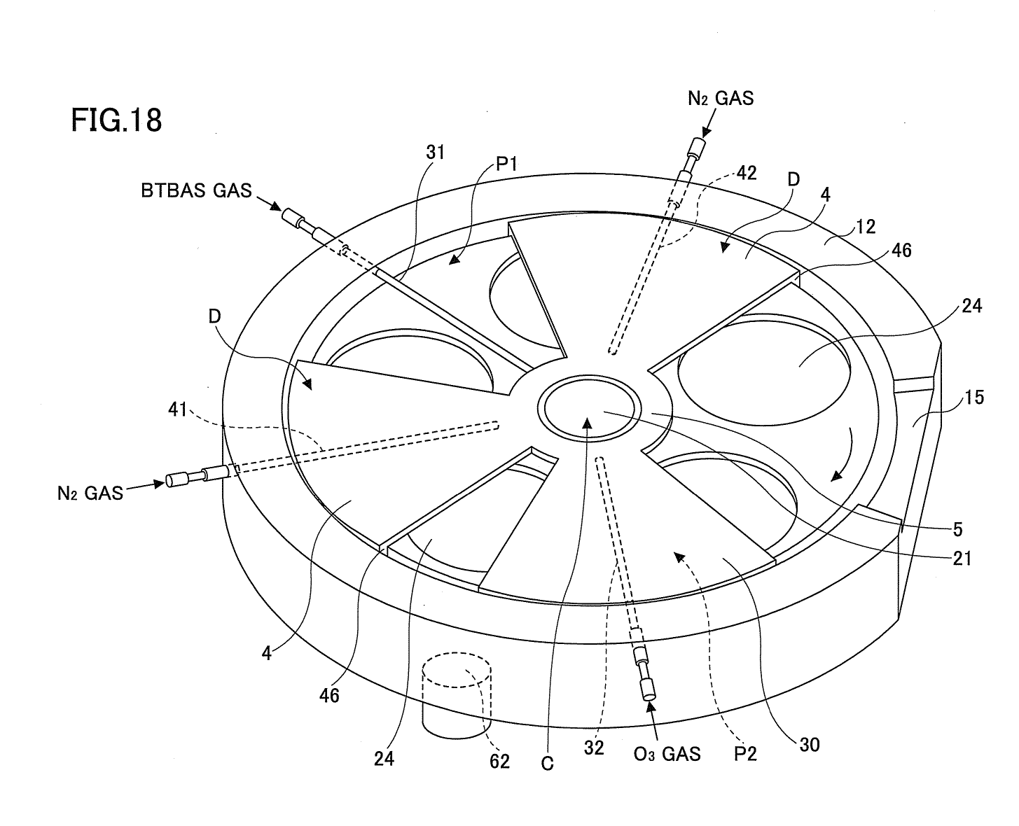

In the above embodiments, the process area P1 and the process area P2 correspond to areas with the ceiling surfaces 45 higher than the ceiling surfaces 44 of the separation areas D. However, at least one of the process areas P1, P2 may have a ceiling surface that is lower than the ceiling surface 45 and opposes the susceptor 2 in both sides of the corresponding reaction gas nozzle 31 or 32. This may impede gas from flowing into a gap between the ceiling surface and the susceptor 2. This ceiling surface may be lower than the ceiling surface 45 and as low as the ceiling plate 44 of the separation area D. FIG. 18 illustrates an example of such a configuration. As shown, a sector-shaped convex portion 30 is arranged in the process area P2 where the O₃ gas is supplied, and the reaction gas nozzle 32 is housed in a groove portion (not shown) formed in the convex portion 30. In other words, although the process area 92 is used for the reaction gas nozzle 32 to supply the reaction gas, the process area P2 is configured in the same manner as the separation area D. Incidentally, the convex portion 30 may be configured in the same manner as the hollow convex portion, an example of which is illustrated in the subsections (a) through (c) of FIG. 14.

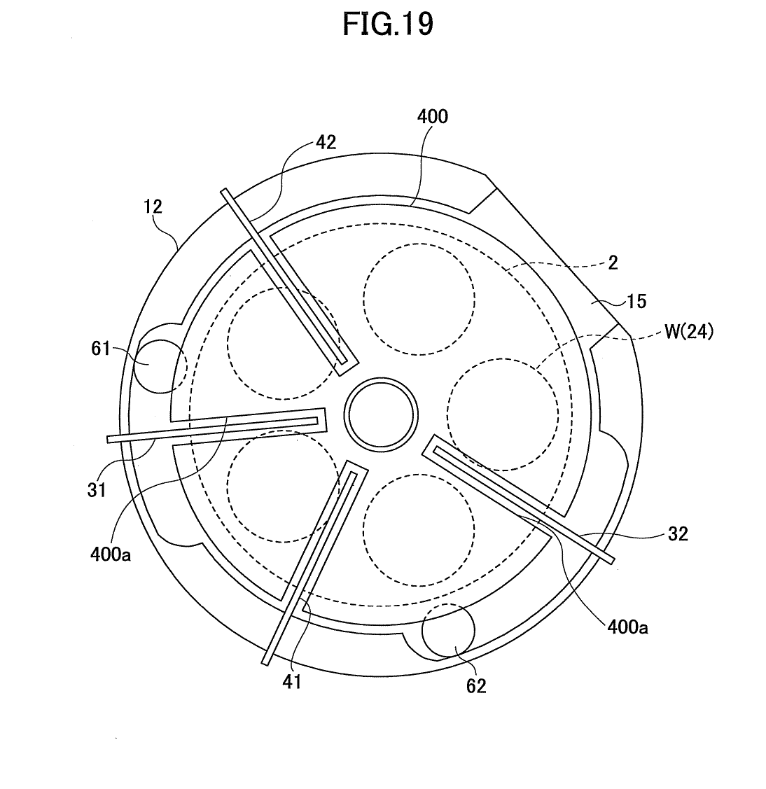

Moreover, the ceiling surface, which is lower than the ceiling surface 45 and as low as the ceiling surface 44 of the separation area D, may be provided for both reaction gas nozzles 31, 32 in order to extend to reach the ceiling surfaces 44 in other embodiments, as shown in FIG. 19, as long as the low ceiling surfaces 44 are provided on both sides of the reaction gas nozzle 41 (42). In other words, another convex portion 400 may be attached on the bottom surface of the ceiling plate 11, instead of the convex portion 4. The convex portion 400 has a shape of substantially a circular plate, opposes substantially the entire top surface of the susceptor 2, has four slots 400a where the corresponding gas nozzles 31, 32, 41, 42 are housed, the slots 400a extending in a radial direction of the convex portion 400, and leaves a thin space below the convex portion 400 in relation to the susceptor 2. A height of the thin space may be comparable with the height h stated above. When the convex portion 400 is employed, the reaction gas ejected from the reaction gas nozzle 31 (32) spreads to both sides of the reaction gas nozzle 31 (32) below the convex portion 400 (or in the thin space) and the separation gas ejected from the separation gas nozzle 41 (42) spreads to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be mixed with the other reaction gas ejected from the reaction gas nozzle 32, thereby realizing an appropriate ALD (or MLD).

Incidentally, the convex portion 400 may be configured by combining the hollow convex portions 4 shown in any one of the subsections (a) through (c) of FIG. 14 in order to eject the reaction gases and the separation gases from the corresponding ejection holes 33 of the corresponding hollow convex portions 4 without using the gas nozzles 31, 32, 41, 42 and the slits 400a.

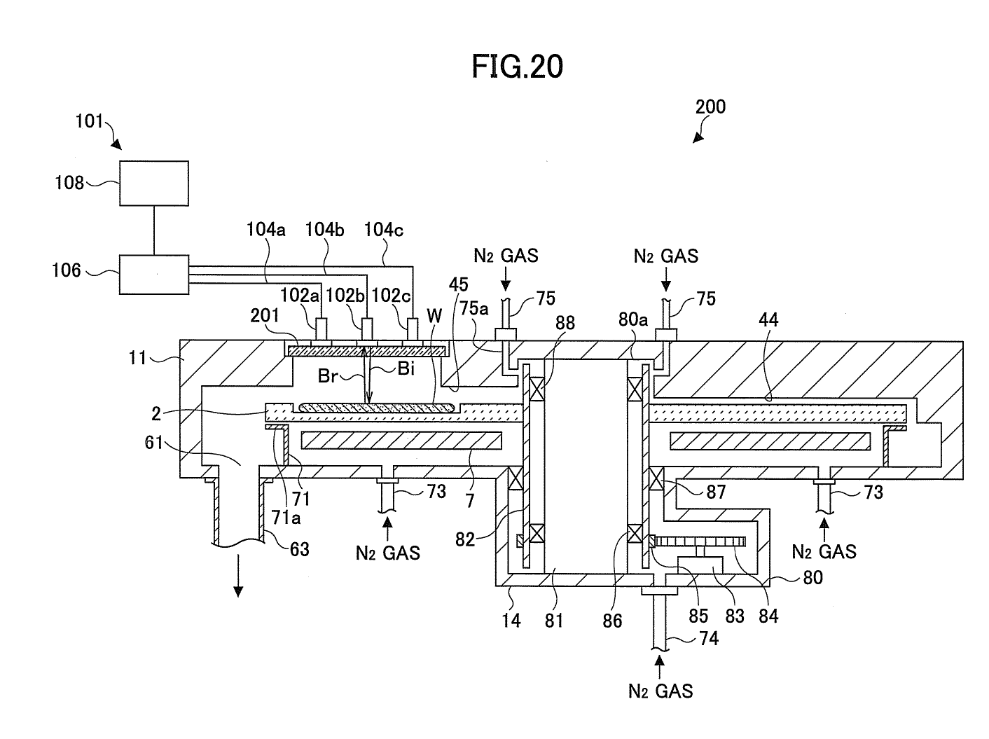

In the above embodiments, the rotational shaft 22 for rotating the susceptor 2 is located in the center portion of the chamber 1. In addition, the space 52 between the core portion 21 and the ceiling plate 11 is purged with the separation gas in order to impede the reaction gases from being intermixed through the center portion. However, the chamber 1 may be configured as shown in FIG. 20 in other embodiments. Referring to FIG. 20, the bottom portion 14 of the chamber body 12 has a center opening to which a housing case 80 is hermetically attached. Additionally, the ceiling plate 11 has a center concave portion 80a. A pillar 81 is placed on the bottom surface of the housing case 80, and a top end portion of the pillar 81 reaches a bottom surface of the center concave portion 80a. The pillar 81 can prevent the first reaction gas (BTBAS) ejected from the first reaction gas nozzle 31 and the second reaction gas (O₃) ejected from the second reaction gas nozzle 32 from being mixed through the center portion of the chamber 1.

In addition, the transparent window 201 made of, for example, quartz glass is hermetically attached to an opening of the ceiling plate 11 via a sealing member (not shown) such as an O-ring. Moreover, the transparent window 201 may have a width substantially equal to a diameter of the wafer W placed on the susceptor 2, and the width extends in a radial direction of the susceptor 2, which enables thickness measurement at various points on the wafer W in the radial direction.

The film deposition apparatus shown in FIG. 20 is provided with the film thickness measurement system 101 for measuring a thickness of the film deposited on the wafer W through the transparent window 201. Therefore, according to this film deposition apparatus 200, the film thickness can be measured during film deposition, thereby terminating the film deposition when the film thickness reaches the target thickness. Namely, the above-described effects can be provided by the film deposition apparatus 200 shown in FIG. 20.

In addition, a rotation sleeve 82 is provided so that the rotation sleeve 82 coaxially surrounds the pillar 81. The rotation sleeve 82 is supported by bearings 86, 88 attached on an outer surface of the pillar 81 and a bearing 87 attached on an inner side wall of the housing case 80. Moreover, the rotation sleeve 82 has a gear portion 85 formed or attached on an outer surface of the rotation sleeve 82. Furthermore, an inner circumference of the ring-shaped susceptor 2 is attached on the outer surface of the rotation sleeve 82. A driving portion 83 is housed in the housing case 80 and has a gear 84 attached to a shaft extending from the driving portion 83. The gear is meshed with the gear portion 85. With such a configuration, the rotation sleeve 82 and thus the susceptor 2 are rotated by a driving portion 83.

A purge gas supplying pipe 74 is connected to an opening formed in a bottom of the housing case 80, so that a purge gas is supplied into the housing case 80. With this, an inner space of the housing case 80 may be kept at a higher pressure than an inner space of the chamber 1, in order to prevent the reaction gases from flowing into the housing case 80. Therefore, no film deposition takes place in the housing case 80, thereby reducing maintenance frequencies. In addition, purge gas supplying pipes 75 are connected to corresponding conduits 75a that reach from an upper outer surface of the chamber 1 to an inner side wall of the concave portion 80a, so that a purge gas is supplied toward an upper end portion of the rotation sleeve 82. Because of the purge gas, the BTBAS gas and the O₃ gas cannot be mixed through a space between the outer surface of the rotation sleeve 82 and the side wall of the concave portion 80a. Although the two purge gas supplying pipes 75 are illustrated in FIG. 20, the number of the pipes 75 and the corresponding conduits 75a may be determined so that the purge gas from the pipes 75 can assuredly prevent gas mixture of the BTBAS gas and the O₃ gas in and around the space between the outer surface of the rotation sleeve 82 and the side wall of the concave portion 80a.

In the embodiment illustrated in FIG. 20, a space between the side wall of the concave portion 80a and the upper end portion of the rotation sleeve 82 corresponds to the ejection hole for ejecting the separation gas. In addition, the center area is configured with the ejection hole, the rotation sleeve 82, and the pillar 81.

Although the two kinds of reaction gases are used in the film deposition apparatus 200 (FIGS. 1, 20 or the like) according to the above embodiment, three or more kinds of reaction gases may be used in other film deposition apparatus according to other embodiments of the present invention. In this case, a first reaction gas nozzle, a separation gas nozzle, a second reaction gas nozzle, a separation gas nozzle, a third reaction gas nozzle and a separation gas nozzle may be located in this order at predetermined angular intervals, each nozzle extending along the radial direction of the susceptor 2. Additionally, the separation areas D including the corresponding separation gas nozzles are configured in the same manner as explained above.

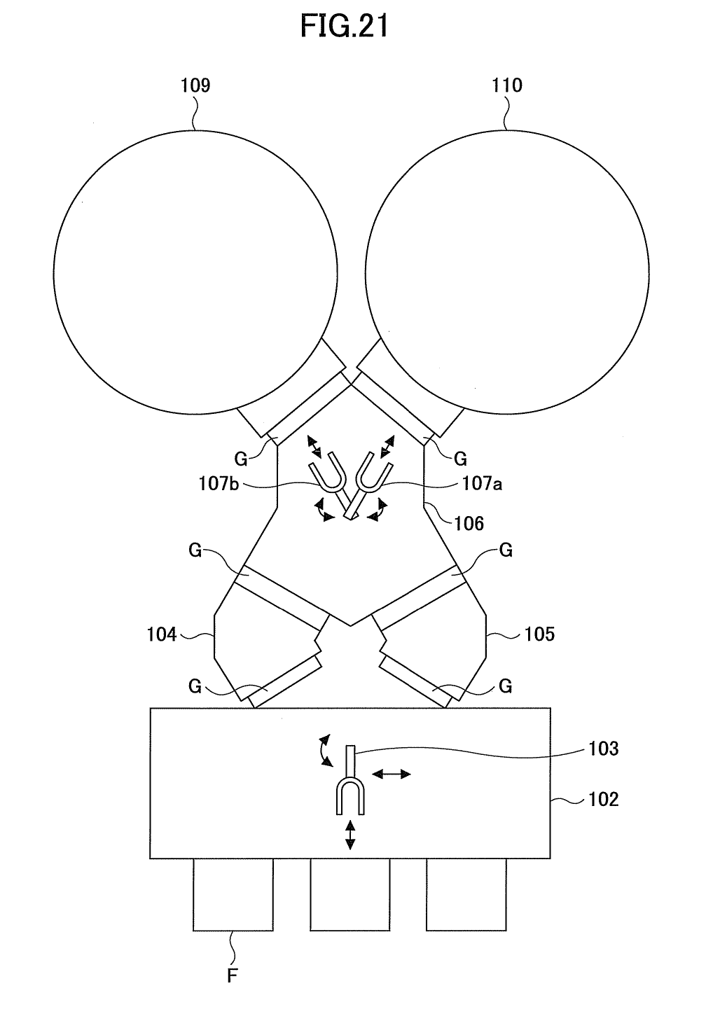

The film deposition apparatus 200 (FIGS. 1, 20, or the like) according to embodiments of the present invention may be integrated into a wafer process apparatus, an example of which is schematically illustrated in FIG. 21. The wafer process apparatus includes an atmospheric transfer chamber 102 in which a transfer arm 103 is provided, a load lock chamber (preparation chamber) 105 whose atmosphere is changeable between vacuum and atmospheric pressure, a vacuum transfer chamber 106 in which two transfer arms 107a, 107b are provided, and film deposition apparatuses 108, 109 according to embodiments of the present invention. In addition, the wafer process apparatus includes cassette stages (not shown) on which a wafer cassette F such as a Front Opening Unified Pod (FOUP) is placed. The wafer cassette F is brought onto one of the cassette stages, and connected to a transfer in/out port provided between the cassette stage and the atmospheric transfer chamber 102. Then, a lid of the wafer cassette (FOUP) F is opened by an opening/closing mechanism (not shown) and the wafer is taken out from the wafer cassette F by the transfer arm 103. Next, the wafer is transferred to the load lock chamber 104 (105). After the load lock chamber 104 (105) is evacuated, the wafer in the load lock chamber 104 (105) is transferred further to one of the film deposition apparatuses 108, 109 through the vacuum transfer chamber 106 by the transfer arm 107a (107b). In the film deposition apparatus 108 (109), a film is deposited on the wafer in such a manner as described above. Because the wafer process apparatus has two film deposition apparatuses 108, 109 that can house five wafers at a time, the ALD (or MLD) mode deposition can be performed at high throughput.

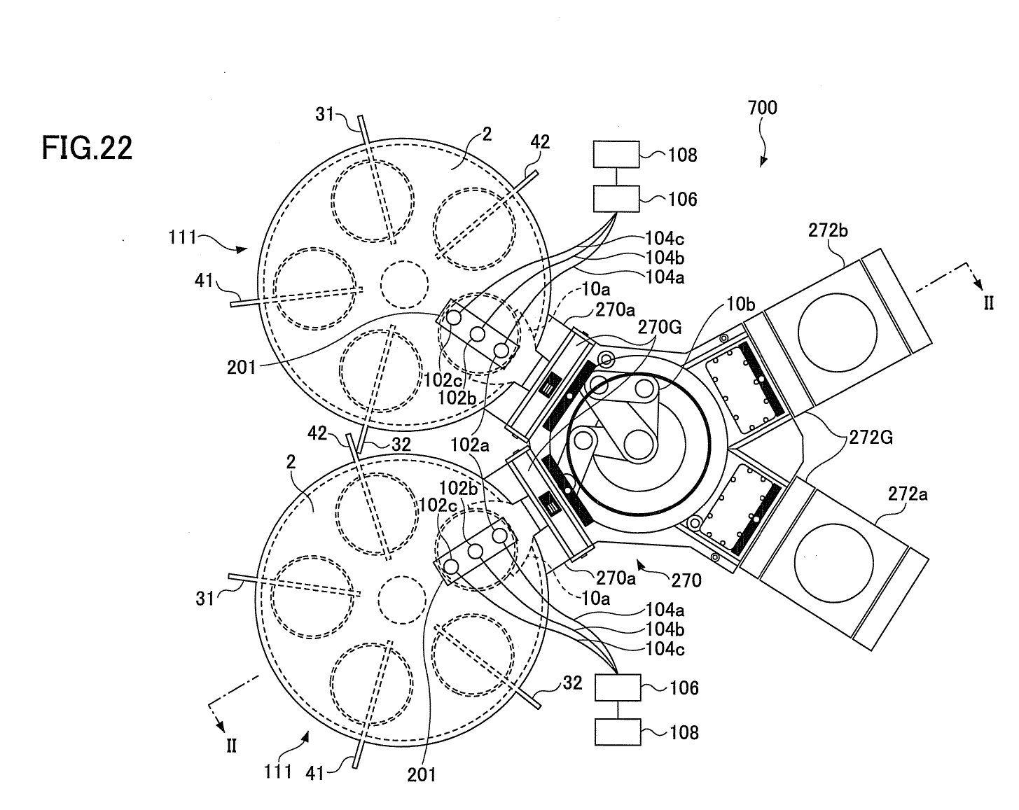

In addition, the film deposition apparatus 200 (FIGS. 1, 20, or the like) according to embodiments of the present invention may be integrated into another substrate process apparatus, an example of which is schematically illustrated in FIG. 22.

FIG. 22 is a plan view of a substrate process apparatus 700 according to an embodiment of the present invention. As shown, the substrate process apparatus 700 includes two vacuum chambers 111; a transfer passage 270a provided to a transfer opening on a side wall of the vacuum chamber 111; a gate valve 270G provided to the transfer passage 270a; a transfer module 270 provided to be in pressure communication with the transfer passage 270a via the gate valve 270G; and load lock chambers 272a, 272b connected to the transfer modules 270 via the corresponding gate valves 272G.

The two vacuum chambers 111 have the same configuration as the vacuum chamber 1. Namely, the vacuum chambers 111 have the transparent window 201 in the ceiling plate. The optical units 102a through 102c are arranged on (or above) the transparent window 201. The optical fiber cables 104a through 104c are connected to the corresponding optical units 102a through 102c and to the film thickness measurement unit 106, which is connected to the control unit 108. In addition, the control unit 108 is connected to a control portion (not shown) of the substrate process apparatus 700, which corresponds to the control portion 100. With such a configuration, the above film thickness measurement can be carried out and the same effects can be demonstrated.

The transfer module 270 includes two transfer arms 10a, 10b, which are retractable and pivotable around a base portion thereof. The transfer arms 10a, 10b can access the corresponding load lock chambers 272a, 272b and the two vacuum chambers 111. With this, the transfer arms 10a, 10b can transfer the wafer W into/out from the vacuum chamber 111 when the gate valve 270G is opened, as shown in FIG. 22. In addition, the transfer arms 10a, 10b can transfer the wafer W into/out from the corresponding load lock chambers 272a, 272b when the gate valve 272G is opened.

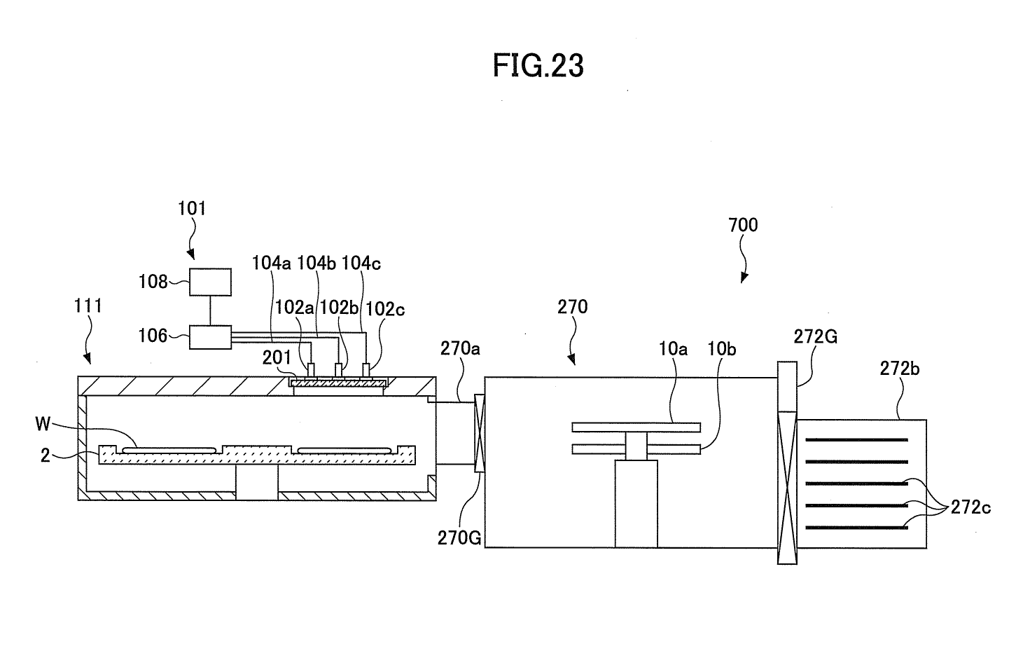

The load lock chamber 272b (272a) includes, for example, a five-staged wafer receiving portions 272c that is elevatable by a driving portion (not shown), as shown in FIG. 23, which is a cross-sectional view taken along II-II line in FIG. 22, and the wafers W are placed on each of the wafer receiving portions 272c. In addition, one of the load lock chambers 272a, 272b may serve as a buffer chamber for temporarily storing the wafers W, and the other of the load lock chambers 272a, 272b may serve as an interface chamber for transferring the wafer W into the film deposition apparatus 700 from an outside apparatus (a process prior to the film deposition process).

Incidentally, the transfer module 270 and the load lock chambers 272a, 272b are connected to corresponding vacuum systems (not shown). The vacuum systems may include, for example, a rotary pump, and a turbo molecular pump, when necessary.

According to the above configurations, the same effect as the film deposition apparatus 200 can be demonstrated, and the ALD can be carried out at higher throughputs.

Incidentally, in the film deposition apparatus 200 (including the film deposition apparatuses included in the substrate process apparatuses), the reaction gas nozzle 31 (32) may be composed of three pipes having different lengths and gas ejection holes. With this, flow rates of the reaction gas through the corresponding pipes may be adjusted in accordance with measurement results obtained from the corresponding optical units 102a through 102c, thereby improving film thickness uniformity over the wafer W.

In addition, while the film thickness measured by the film thickness measurement system 101 is compared with the target thickness by the control unit 108 of the film thickness measurement system 101 in the above embodiments, information indicating the measured film thickness may be transmitted from the control unit 108 to the control portion 100, and the comparison and determination may be carried out in the control portion 100.

Moreover, while the phase modulation type ellipsometer is exemplified for the film thickness measurement system 101 in the above embodiments, a null ellipsometer, a rotating polarizer type ellipsometer, a rotating analyzer type ellipsometer, or a rotating compensator type ellipsometer may be used for the film thickness measurement system 101. In addition, a halogen lamp, a deuterium lamp, or the like may be used as the light source 106a, not being limited to the xenon lamp.

Furthermore, an additional opening may be formed in the ceiling plate 11, and an additional transparent window may be attached to the additional opening. In this case, the light emitting portion LE is provided for one transparent window 201 in order to emit the light beam Bi, and the light detecting portion D is separately provided for the additional transparent window in order to receive the light beam Br reflected from the upper surface of the wafer W. With this, an incident angle of the light beam Bi from the light emitting portion LE with respect to a normal line of the upper surface of the wafer W can be easily set to a Brewster's angle as close as possible, thereby improving measurement accuracy.

In addition, the film thickness measurement system 101 includes three optical units 102a through 102c in the above embodiments, but may have four or more optical units in other embodiments. The number of the optical units may be determined depending on a size of the wafer W.

Moreover, the film thickness measurement system 101 may be configured to measure the film thickness by utilizing multiple reflections taking place between an upper surface of the film deposited on the wafer W and a boundary face of the film and the wafer (or the underlying film).

While the present invention has been explained with reference to the foregoing embodiments and examples, the present invention is not limited to the disclosed embodiments and examples, but may be modified or altered with in the scope of the accompanying claims.

What is claimed is:

1. A film deposition apparatus for depositing a film on a substrate by carrying out a cycle of alternately supplying to the substrate at least two kinds of reaction gases that react with each other to produce a layer of a reaction product in a chamber, the film deposition apparatus comprising:
a susceptor rotatably provided in the chamber and having in one surface thereof a substrate receiving area in which the substrate is placed;
a window portion hermetically provided to the chamber so that the window portion opposes the susceptor in the chamber;
a film thickness measurement portion that optically measures a thickness of a film deposited on the substrate placed in the substrate receiving area, through the window portion;
a first reaction gas supplying portion configured to supply a first reaction gas to the one surface;
a second reaction gas supplying portion configured to supply a second reaction gas to the one surface, the second reaction gas supplying portion being separated from the first reaction gas supplying portion along a rotation direction of the susceptor;
a separation area located along the rotation direction between a first process area in which the first reaction gas is supplied and a second process area in which the second reaction gas is supplied;
a center area that is located substantially in a center portion of the chamber, configured to separate the first process area and the second process area, and has an ejection hole that ejects a first separation gas along the one surface; and
an evacuation opening provided in the chamber in order to evacuate the chamber;
wherein the separation area includes a separation gas supplying portion that supplies a second separation gas, and a ceiling surface that creates in relation to the one surface of the susceptor a thin space in which the second separation gas may flow from the separation area to the process area side in relation to the rotation direction.

2. The film deposition apparatus recited in claim 1, wherein the film thickness measurement portion includes:
plural light emitting portions that emit light to plural corresponding points on the substrate; and
plural light detecting portions that receive reflection light of the light emitted from the plural light emitting portions to the plural corresponding points on the substrate.

3. The film deposition apparatus recited in claim 1, further comprising a control part configured to stop film deposition when a measured film thickness of the film deposited on the substrate, the film thickness being measured by the film thickness measurement portion, is compared with a target thickness, and it is determined as a result of the comparison that the measured film thickness is greater than or equal to the target thickness.

4. The film deposition apparatus recited in claim 1, wherein the film thickness measurement portion includes an ellipsometer.

5. A film deposition method for depositing a film on a substrate by carrying out a cycle of alternately supplying to the substrate at least two kinds of reaction gases that react with each other to produce a layer of a reaction product in a chamber, the film deposition method comprising steps of:
placing the substrate in a substrate receiving area defined in one surface of a susceptor rotatably provided in the chamber;
rotating the susceptor on which the substrate is placed;
supplying a first reaction gas to the one surface of the susceptor from a first reaction gas supplying portion;
supplying a second reaction gas to the one surface of the susceptor from a second reaction gas supplying portion separated from the first reaction gas supplying portion along a rotation direction of the susceptor;
supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor;
supplying a second separation gas from an ejection hole formed in a center area located in a center portion of the chamber;
evacuating the chamber; and
measuring a film thickness of a film deposited on the substrate placed on the susceptor rotated in the step of rotating the susceptor.

6. The film deposition method recited in claim 5, wherein the step of measuring the film thickness includes steps of:
emitting light to the substrate on the susceptor rotated in the step of rotating the susceptor;
receiving reflection light of the light emitted to the substrate in the step of emitting the light; and
calculating the film thickness of the film deposited on the substrate by utilizing a spectroscopic intensity of the reflection light received in the step of receiving the reflection light.

7. The film deposition method recited in claim 6, wherein plural light beams are emitted to the substrate, and plural reflection light beams of the corresponding light beams emitted to the substrate are received in the step of emitting the light; and
wherein the film thickness of the film is calculated by utilizing spectroscopic intensities of the plural reflection light beams.

8. The film deposition method recited in claim 6, further comprising a step of comparing a film thickness calculated in the step of calculating the film thickness with a target thickness of the film.

9. The film deposition method recited in claim 8, further comprising a step of stopping supplying the first reaction gas and the second reaction gas when it is determined that the calculated film thickness is greater than or equal to the target thickness as a result of the step of comparing.

10. The film deposition method recited in claim 6, wherein the film thickness is calculated by ellispometry in the step of calculating.

11. A computer readable storage medium storing a computer program for causing a film deposition apparatus recited in claim 1 to carry out a film deposition method comprising steps of:
placing the substrate in the substrate receiving area defined in one surface of the susceptor rotatably provided in the chamber;
rotating the susceptor on which the substrate is placed;
supplying the first reaction gas to the one surface of the susceptor from a first reaction gas supplying portion;
supplying the second reaction gas to the one surface of the susceptor from the second reaction gas supplying portion separated from the first reaction gas supplying portion along the rotation direction of the susceptor;
supplying the first separation gas from the separation gas supplying portion provided in the separation area located between the first process area in which the first reaction gas is supplied from the first reaction gas supplying portion and the second process area in which the second reaction gas is supplied from the second reaction gas supplying portion, in order to flow the first separation gas from the separation area to the process area relative to the rotation direction of the susceptor in the thin space created between the ceiling surface of the separation area and the susceptor;
supplying the second separation gas from the ejection hole formed in the center area located in the center portion of the chamber;
evacuating the chamber; and
measuring a film thickness of the film deposited on the substrate placed on the susceptor rotated in the step of rotating the susceptor.
